(19) United States
(12) Patent Application Publication
(10) Pub. No.: US 2015/0208560 A1
(43) Pub. Date: Jul. 23, 2015

(54) HOLDING HEAD, FEEDING APPARATUS, FEEDING METHOD, IMPLEMENTING APPARATUS, IMPLEMENTING METHOD, AND ELECTRONIC DEVICE

(71) Applicant: Sony Corporation, Tokyo (JP)

(72) Inventors: Shoichi Baba, Kanagawa (JP); Norio Fukasawa, Kanagawa (JP)

(73) Assignee: Sony Corporation, Tokyo (JP)

(21) Appl. No.: 14/589,146

(22) Filed: Jan. 5, 2015

(30) Foreign Application Priority Data
Jan. 21, 2014 (JP) 2014-008748
Aug. 7, 2014 (JP) 2014-161313

(51) Int. Cl. H05K 13/02; H05K 13/04; H05K 1/18; H05K 13/00

(52) U.S. Cl. CPC H05K 13/02; H05K 13/0069; H05K 13/0084; H05K 13/0452; H05K 13/046; H05K 13/021; H05K 13/022; H05K 1/18

(57) ABSTRACT

Provided is a holding head, including: a holder unit including a plurality of holders, the plurality of holders extending in a first direction, the plurality of holders being arrayed in a second direction at a predetermined pitch, the first direction being different from the second direction, each of the plurality of holders being capable of holding an object group, the object group including a plurality of objects arrayed in series in the first direction out of a plurality of objects arranged two-dimensionally; and a support supporting the holder unit.

### CROSS REFERENCE TO RELATED APPLICATIONS

This application claims the benefit of Japanese Priority Patent Application JP 2014-008748 filed Jan. 21, 2014 and Japanese Priority Patent Application JP 2014-161313 filed Aug. 7, 2014, the entire contents of which are incorporated herein by reference.

### BACKGROUND

The present technology relates to a holding head, a feeding apparatus, and a feeding method capable of feeding components or the like. The present technology further relates to an implementing apparatus, an implementing method, and an electronic device using them.

Japanese Patent Application Laid-open No. 2012-94623 discloses a carrying operation used in assembly operations or the like in various industrial fields. According to the carrying operation, electronic components such as resisters and capacitors are uplifted and carried to predetermined positions. Such a carrying operation is widely used. As shown in FIG. 2 of Japanese Patent Application Laid-open No. 2012-94623, a carrying device includes a catch plate 11 and two release plates 12. The catch plate 11 is provided on a tip of a catcher 1 configured to catch a component. An adhesive rubber 2 is fixed on the catch plate 11. The catch plate 11 is sandwiched between the two release plates 12. The catch plate 11 is slidable vertically. The adhesive rubber 2 fixed on the catch plate 11 pops up from the tip of the release plates 12, and is retracted. This structure may help to carry minute components with ease (see paragraph [0017] etc. of specification of Japanese Patent Application Laid-open No. 2012-94623).

### SUMMARY

It is desirable to simplify a member (for example, the above-mentioned carrying device etc.) configured to hold components to feed such electronic components. It is further desirable to feed components appropriately with the smaller number of feeding.

In view of the above-mentioned circumstances, it is desirable to provide a holding head, a feeding apparatus, and a feeding method, each of which has a simple structure and is capable of reducing the number of feeding. It is further desirable to provide an implementing apparatus, an implementing method, and an electronic device using them.

According to an embodiment of the present technology, there is provided a holding head, including:

a holder unit including a plurality of holders, the plurality of holders extending in a first direction, the plurality of holders being arrayed in a second direction at a predetermined pitch, the first direction being different from the second direction, each of the plurality of holders being capable of holding an object group, the object group including a plurality of objects arrayed in series in the first direction out of a plurality of objects arranged two-dimensionally; and

a support supporting the holder unit.

In the holding head, the holders extend in the first direction, and are arrayed in the second direction at a predetermined pitch. The single holder is capable of holding a plurality of objects arrayed in series in the first direction. So the number of feeding can be reduced. Moreover the holding head may have a simple structure.

The plurality of holders may protrude in a third direction, the third direction being perpendicular to the first direction and the second direction.

The plurality of holders protruding in the third direction are capable of holding components reliably.

At least one of the plurality of holders may include a first transmitting portion, the first transmitting portion being capable of transmitting visible light in the third direction, and the support may include a second transmitting portion, the second transmitting portion being capable of transmitting the visible light in the third direction, the visible light passing through the first transmitting portion.

With this structure, a user can confirm the objects visually through the first and second transmitting portions. Moreover an image of the objects can be taken. As a result, the relative position of the objects and the holding head can be adjusted with a high degree of accuracy.

The first transmitting portion may be made of a transparent material, the transparent material being configured to transmit the visible light, and the second transmitting portion may be made of a transparent material, the transparent material being configured to transmit the visible light.

As described above, the first transmitting portion may be made of a transparent material, and the second transmitting portion may be made of a transparent material.

Each of the plurality of holders may be made of a first transparent material, and the support may be made of a second transparent material.

As described above, the plurality of holders may be made of a transparent material, and the support may be made of a transparent material.

The first direction may be perpendicular to the second direction.

It is possible to feed the objects such that the objects are arrayed in the two directions perpendicular to each other, and to reduce the number of feeding.

Each of the plurality of holders may hold the object group by using adhesive power.

The structure of the holding head, which uses adhesive power, can be simplified. Moreover it is easy to manufacture the holding head.

The cross-sectional shape of each of the plurality of holders seen in the first direction may be substantially trapezoidal, the long side of the trapezoid being the support side, the short side being the side in contact with the objects.

With this structure, it is easy to wash the plurality of holder units and the like.

The holder unit may include a coupler, the coupler coupling the plurality of holders.

The plurality of holder units may be independent of each other. Alternatively, the coupler may couple the plurality of holder units.

According to an embodiment of the present technology, there is provided a feeding apparatus, including:

at least one first holding head, the first holding head including a plurality of first holders, the plurality of first holders extending in a first direction, the plurality of first holders being arrayed in a second direction at a first pitch, the first direction being different from the second direction, each of the plurality of first holders being capable of holding a first object group, the first object group including a plurality of objects arrayed in series in the first direction out of a plurality of objects arranged two-dimensionally; and

a driver configured
to transfer the at least one first holding head, and
to cause the at least one first holding head to hold the first object groups.

In the feeding apparatus, the holder extends in the first direction, and includes the first holding heads arrayed in the second direction at a predetermined pitch. The one holder is capable of holding the plurality of objects arrayed in series in the first direction. So the number of feeding can be reduced. Moreover the first holding head may have a simple structure.

The feeding apparatus may further include a second holding head including a plurality of second holders, the plurality of second holders extending in the second direction, the plurality of second holders being arrayed in the first direction at a second pitch, each of the plurality of second holders being capable of holding a second object group, the second object group including a plurality of objects arrayed in series in the second direction out of the plurality of objects arranged two-dimensionally, in which

the driver may be configured to cause the second holding head to hold a plurality of second object groups, the second object group including a plurality of objects arrayed in series in the second direction at the first pitch out of the plurality of objects held by the first holding head.

In the feeding apparatus, the second holding head holds the plurality of objects held by the first holding head. As a result, it is possible to feed the plurality of objects such that the plurality of objects are arrayed in the second direction at the first pitch and arrayed in the first direction at the second pitch, and to reduce the number of feeding.

The at least one first holding head may include a plurality of first holding heads, and the driver may be configured to fix the plurality of first holding heads such that the plurality of first object groups held by the plurality of first holding heads are arrayed in series in the first direction or arrayed in series in the second direction at the first pitch, and to cause the second holding head to hold the plurality of objects held by the plurality of first holding heads.

In the feeding apparatus, the plurality of first holding heads are fixed such that the first object groups are arrayed in series in the first direction or the second direction. Further, the second holding head holds the plurality of held objects in this situation. As a result, the number of feeding can be reduced.

The feeding apparatus may further include a mount, the plurality of first object groups held by the first holding head being mounted on the mount, in which the driver may be configured to cause the second holding head to hold a plurality of second object groups, the second object group including a plurality of objects arrayed in series in the second direction at the first pitch out of the plurality of objects mounted on the mount.

In the feeding apparatus, the first object groups held by the first holding head are mounted on the mount. Then the second holding head holds the plurality of objects mounted on the mount. As a result, the number of feeding can be reduced.

The driver may be configured to cause the first holding head to hold the plurality of first object groups a plurality of times such that the plurality of first object groups held by the first holding head are arrayed on the mount in series in the first direction or arrayed on the mount in series in the second direction at the first pitch.

In the feeding apparatus, the first holding head holds the first object groups a plurality of times such that the first object groups are arrayed in series in the first direction or the second direction. Then the second holding head holds the plurality of mounted objects. As a result, the number of feeding can be reduced.

The at least one first holding head may include a plurality of first holding heads, and the driver may be configured to cause the plurality of first holding heads to hold the plurality of first object groups such that the plurality of first object groups held by the plurality of first holding heads are arrayed on the mount in series in the first direction or arrayed on the mount in series in the second direction at the first pitch.

In the feeding apparatus, the plurality of first holding heads mount the first object groups on the mount. Then the second holding head holds the plurality of mounted objects. As a result, the number of feeding can be reduced.

The driver may be configured to cause the plurality of first holders to extend in a direction, in which the plurality of first object groups mounted on the mount being arrayed at the first pitch, and to cause the first holding head to hold the plurality of first object groups in this situation.

In the feeding apparatus, the first holding head holds the first object groups mounted on the mount again. As a result, the number of feeding can be reduced.

At least one of the plurality of first holders may include a first transmitting portion, the first transmitting portion being capable of transmitting visible light in a third direction, the third direction being perpendicular to the first direction and the second direction, and the feeding apparatus may further include an image-taking unit configured to take an image with the visible light passing through the first transmitting portion, and an adjusting unit configured to adjust the relative position of the at least one first holding head and the first object groups based on the image taken by the image-taking unit.

With this structure, it is possible to adjust the relative position of the first object groups and the first holding head with a high degree of accuracy.

At least one of the plurality of second holders may include a second transmitting portion, the second transmitting portion being capable of transmitting visible light in the third direction, the image-taking unit may be configured to take an image with the visible light passing through the second transmitting portion, and the adjusting unit may be configured to adjust the relative position of the second holding head and the second object groups based on the image taken by the image-taking unit.

With this structure, it is possible to adjust the relative position of the second object groups and the second holding head with a high degree of accuracy.

According to an embodiment of the present technology, there is provided a feeding method, including:

preparing a plurality of objects arranged two-dimensionally in an original place;

holding a plurality of first object groups with a plurality of first holders of a first holding head, the plurality of first holders extending in a first direction, the plurality of first holders being arrayed in a second direction at a first pitch, the first direction being different from the second direction, each of the plurality of first object groups including a plurality of objects arrayed in series in the first direction out of the plurality of objects; and

feeding the plurality of held first object groups to a target place.

The feeding method may further include: holding a plurality of second object groups with a plurality of second holders of a second holding head, the plurality of second holders extending in the second direction, the plurality of second holders being arrayed in the first direction at a second pitch, each of the plurality of second object groups including a plurality of objects arrayed in series in the second direction at the first pitch out of the plurality of objects held by the first holding head; and feeding the plurality of held second object groups to the target place.

According to an embodiment of the present technology, there is provided an implementing apparatus, including:

a first holding head including a plurality of first holders, the plurality of first holders extending in a first direction, the plurality of first holders being arrayed in a second direction at a first pitch, the first direction being different from the second direction, each of the plurality of first holders being capable of holding a first component group, the first component group including a plurality of components arrayed in series in the first direction out of a plurality of components arranged two-dimensionally; and

an implementing unit configured to implement a plurality of first component groups held by the first holding head on a board.

With this structure, it is possible to reduce the amount of time for implement.

The implementing apparatus may further include:

a second holding head including a plurality of second holders, the plurality of second holders extending in the second direction, the plurality of second holders being arrayed in the first direction at a second pitch, each of the plurality of second holders being capable of holding a second component group, the second component group including a plurality of components arrayed in series in the second direction out of the plurality of components arranged two-dimensionally; and

a driver configured to cause the second holding head to hold a plurality of second component groups, the second component group including a plurality of components arrayed in series in the second direction at the first pitch out of the plurality of components held by the first holding head, in which

the implementing unit is configured to implement the plurality of second component groups held by the second holding head on the board.

With this structure, it is possible to implement the plurality of components such that the plurality of components are arrayed in the first and second directions, and to reduce the processing time.

According to an embodiment of the present technology, there is provided an implementing method, including:

preparing a plurality of components arranged two-dimensionally in an original place;

holding a plurality of component groups with a plurality of holders of a holding head, the plurality of holders extending in a first direction, the plurality of holders being arrayed in a second direction at a predetermined pitch, the first direction being different from the second direction, each of the plurality of component groups including a plurality of components arrayed in series in the first direction out of the plurality of components; and

implementing the plurality of held component groups on a board.

According to an embodiment of the present technology, there is provided an electronic device, including a board manufactured by using the implementing method.

According to another embodiment of the present technology, there is provided a feeding method, including:

preparing a plurality of objects arranged two-dimensionally in an original place;

holding a plurality of object groups, the object group including a plurality of objects arrayed in series in a first direction out of the plurality of objects, the plurality of object groups being arrayed in a second direction, the first direction being different from the second direction; and

feeding the plurality of held object groups to a target place.

According to the feeding method, the plurality of object groups arrayed in the second direction are held. As a result, the number of feeding can be reduced.

According to another embodiment of the present technology, there is provided a holding head, including:

a holder including a first transmitting portion, the first transmitting portion being capable of transmitting visible light in a predetermined direction, the holder coming in contact with an object in the predetermined direction, the holder being capable of holding the object by using adhesive power; and

a support supporting the holder, the support including a second transmitting portion, the second transmitting portion being capable of transmitting the visible light in the predetermined direction, the visible light passing through the first transmitting portion.

As described above, according to the present technology, it is possible to provide a holding head, a feeding apparatus, and a feeding method, each of which has a simple structure and is capable of reducing the number of feeding. It is further possible to provide an implementing apparatus, an implementing method, and an electronic device using them. Note that the above-mentioned effects are not necessarily limited. Any effect described in the present disclosure may be obtained.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a diagram illustrating an example of the present component-feeding technology;

FIG. 2 is a diagram illustrating an example of the present component-feeding technology;

FIGS. 3A-B are diagrams schematically showing an example of the structure of a feeding apparatus of the first embodiment;

FIGS. 4A-C are diagrams schematically showing an example of the structure of a holding head;

FIG. 5 is a flowchart showing an example of the behavior of the feeding apparatus of the first embodiment;

FIG. 6 is a diagram schematically illustrating the steps of FIG. 5;

FIG. 7 is a diagram schematically showing a modification example of the component-feeding technology of the first embodiment;

FIG. 8 is a diagram schematically illustrating a component-feeding technology of a comparative example;

FIGS. 9A-B are diagrams schematically showing an example of the structure of a feeding apparatus according to a second embodiment;

FIG. 10 is a flowchart showing an example of the behavior of the feeding apparatus of the second embodiment;

FIG. 11 is a diagram schematically illustrating the steps of FIG. 10;

FIG. 12 is a diagram schematically showing a modification example of the component-feeding technology of the second embodiment;

FIG. 13 is a diagram schematically showing an example of the structure of a feeding apparatus according to the third embodiment;

FIG. 14 is a flowchart showing an example of the behavior of the feeding apparatus of the third embodiment;

FIG. 15 is a diagram schematically showing a modification example of the component-feeding technology of the third embodiment;

FIG. 16 are tables showing the number of feeding of each of the above-mentioned embodiments and the number of feeding of the above-mentioned comparative example;

FIGS. 17A-B are diagrams schematically illustrating the front sides and the back sides of the components 15 to be fed;

FIG. 18 is a diagram schematically showing an example of the structure of a holding head according to another embodiment;

FIG. 19 is a diagram schematically showing an example of the structure of a holding head according to another embodiment;

FIG. 20 is a diagram schematically showing an example of the structure of a holding head according to another embodiment;

FIG. 21 is a diagram illustrating another example of the present component-feeding technology;

FIG. 22 is a diagram schematically showing an example of the structure of an implementing apparatus of the present technology;

FIG. 23 is a diagram illustrating an example of the structure of a holding head according to another embodiment;

FIGS. 24A-B are diagrams schematically showing an example of the structure of a feeding apparatus including the holding head of FIG. 23;

FIGS. 25A-C are diagrams schematically showing other structural examples of first and second transmitting portions transmitting visible light;

FIGS. 26A-C are diagrams schematically showing structural examples of holding heads of other embodiments; and

FIGS. 27A-E are diagrams each illustrating the focus of a camera, which takes images of components to be held.

### DETAILED DESCRIPTION OF EMBODIMENTS

Hereinafter, embodiments of the present technology will be described with reference to the drawings.

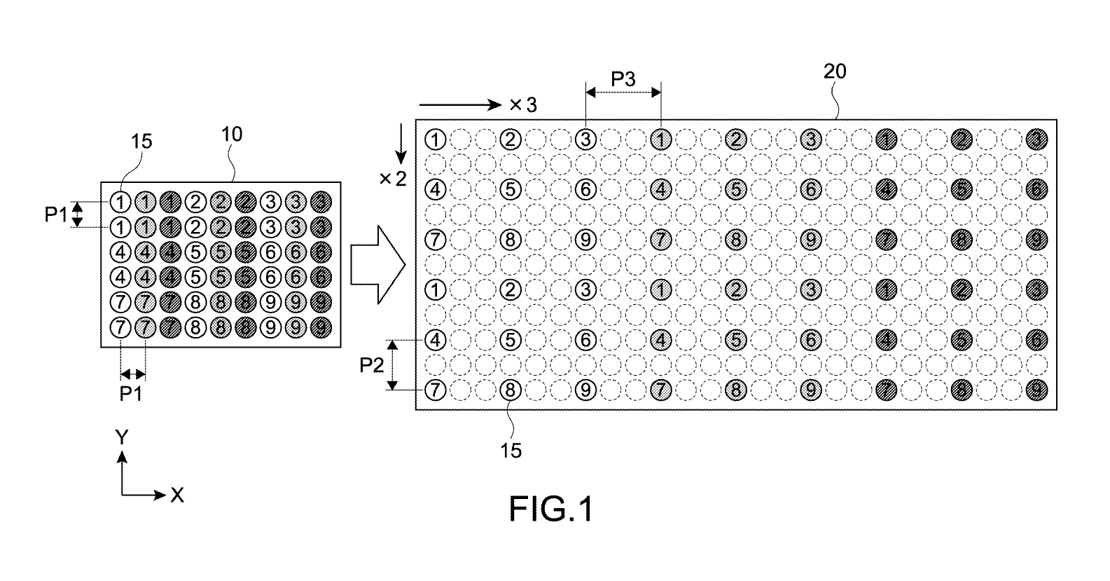

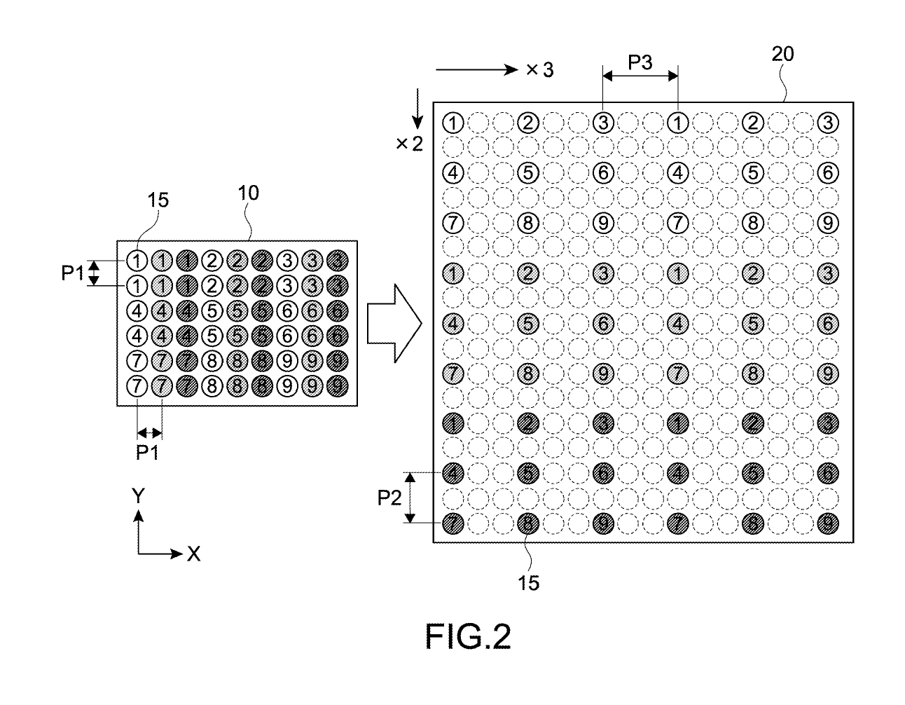

Each of FIG. 1 and FIG. 2 is a diagram illustrating an example of the present component-feeding technology. As shown in FIG. 1, a plurality of components 15 are arranged on an original board 10, and are fed to predetermined positions on a target board 20.

The plurality of components 15 are arranged two-dimensionally on the original board 10. In this embodiment, nine components 15 are arranged in series in the X direction. Six components 15 are arranged in series in the Y direction. The X direction is perpendicular to the Y direction. In other words, fifty-four components 15 are arranged on the original board 10 in total.

The plurality of components 15 are arranged in series in the X direction at predetermined pitches P1. Moreover the plurality of components 15 are arranged in series in the Y direction at the same pitches P1. In this embodiment, the plurality of components 15 correspond to a plurality of objects. Moreover the X direction corresponds to a second direction, and the Y direction corresponds to a first direction. The size of the pitch P1 is not limited, and is about 10 μm to 10,000 μm, for example. The size of the pitch in the X direction may be different from the size of the pitch in the Y direction.

Any method may be employed to arrange the plurality of components 15 on the original board 10. Any method may be employed to hold the components 15 by the original board 10. In this embodiment, the original board 10 holds the plurality of components 15 by using predetermined adhesive power. Any structure may be employed to realize the adhesive power.

In this embodiment, the plurality of components 15 are light emitting devices such as LDs (Laser Diodes) or LEDs (Light Emitting Diodes). Alternatively, the objects to be fed may be electronic components such as resisters or capacitors, other arbitrary devices, or the like.

The size of the component 15 to be fed is not limited. For example, the size of the component to be fed is about several tens of μm to a few cm. A device or the like larger than that may be fed. Moreover the above-mentioned pitch P1 may be selected based on the size of the component 15.

The target board 20 is larger than the original board 10. According to the present component-feeding technology, the plurality of components 15 are to be arranged on the target board 20. As shown in FIG. 1, the plurality of components 15 are arranged in series in the X direction at predetermined pitches P3. Moreover the plurality of components 15 are arranged in series in the Y direction at predetermined pitches P2. In this embodiment, the predetermined pitch P3 is three times as large as the pitch P1 between the plurality of components 15 arranged on the original board 10. Moreover the predetermined pitch P2 is twice as large as the pitch P1.

In other words, in the feeding example of FIG. 1, the pitch between the plurality of fed components 15 is three times in the X direction as large as the pitch between the plurality of components 15 arranged on the original board 10. Moreover the pitch between the plurality of fed components 15 is twice in the Y direction as large as the pitch between the plurality of components 15 arranged on the original board 10. In the example of FIG. 1, the enlargement factor in the X direction is three, and the enlargement factor in the Y direction is two. In other words, the enlargement factor as a whole is six.

Even if the pitch on the original board 10 in the X direction is different from the pitch in the Y direction, according to the present technology, the pitches in the both directions are enlarged and a plurality of components are fed. Note that the pitches are enlarged when arraying light emitting devices on a predetermined surface to manufacture a display, for example. As a matter of course, the pitches may be enlarged for any other purpose.

In FIG. 1, the number of the components arrayed on the original board in the X direction is the same as the number of the components arrayed on the target board in the X direction, and the number of the components arrayed on the original board in the Y direction is the same as the number of the components arrayed on the target board in the Y direction. However, the present technology is applicable to other situations. For example, as shown in FIG. 2, six components 15 may be arranged on the target board 20 in the X direction at the pitches P3, and nine components 15 may be arranged in the Y direction at the pitches P2. As described above, the present technology is applicable to the situation in which the number of the components 15 on the original board in the X direction is different from the number of the components 15 on the target board in the X direction and the number of the components 15 on the original board in the Y direction is different from the number of the components 15 on the target board in the Y direction. In the present disclosure, in the feeding example of FIG. 1, “the enlargement factor in the X direction is three, and the enlargement factor in the Y direction is two”. Also in the feeding example of FIG. 2, “the enlargement factor in the X direction is three, and the enlargement factor in the Y direction is two”.

### First Embodiment

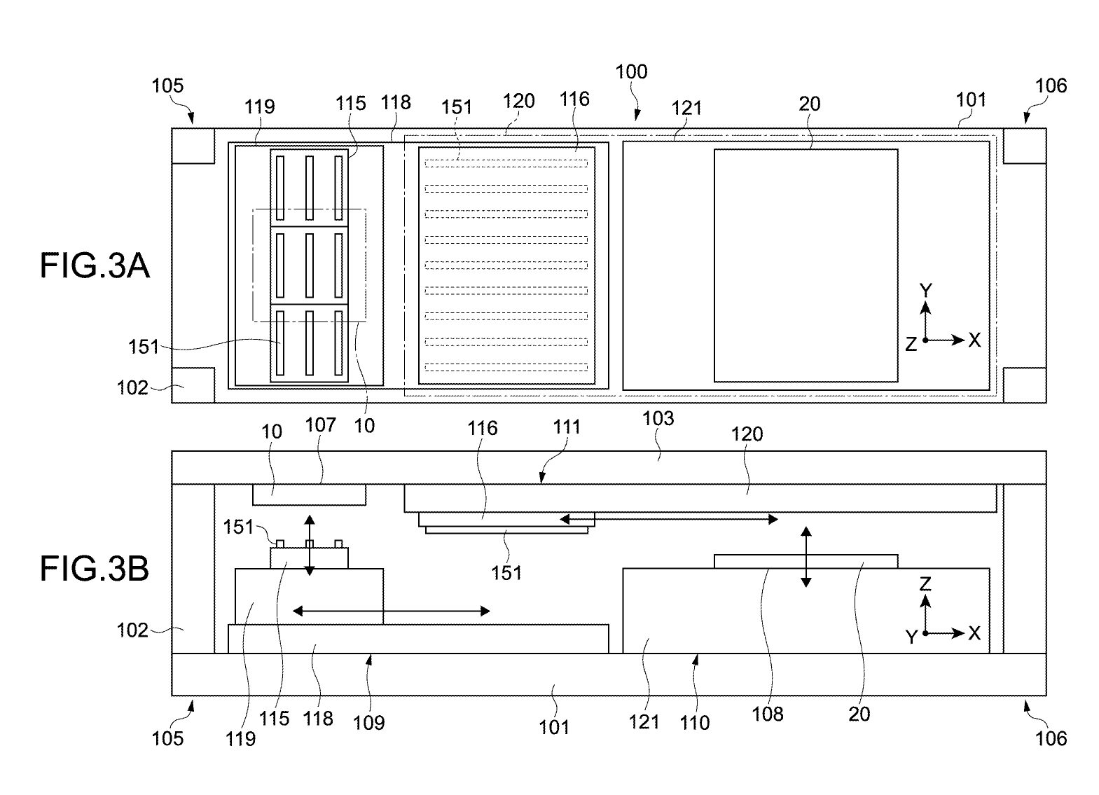

FIGS. 3A-B are diagrams schematically showing an example of the structure of a feeding apparatus according to a first embodiment of the present technology. FIG. 3A is a top plan view showing a feeding apparatus 100. FIG. 3B is a side view showing the feeding apparatus 100. Note that FIG. 3A does not show a top panel 103 shown in FIG. 3B.

The feeding apparatus 100 includes a base 101, four support rods 102, and a top panel 103. The top planer shape of the base 101 is a rectangle. The four support rods 102 are provided on the four corners of the base 101. The top panel 103 is mounted on the four support rods 102. The planer shape of the top panel 103 is approximately the same as the planer shape of the base 101. In other words, the planer shape of the feeding apparatus 100 as a whole is a rectangle. Hereinafter, one end of the feeding apparatus 100 (the base 101, the top panel 103) in the long axis direction (parallel to X direction) will be referred to as a first end 105, and the other end will be referred to as a second end 106.

As shown in FIGS. 3A-B, the feeding apparatus 100 includes a first board holder 107 and a second board holder 108. The first board holder 107 holds the original board 10. The second board holder 108 holds the target board 20. Moreover the feeding apparatus 100 includes an XYZ transferring mechanism 109, a Z transferring mechanism 110, and an XY transferring mechanism 111. The XYZ transferring mechanism 109 and the Z transferring mechanism 110 are arranged on the base 101. The XY transferring mechanism 111 is arranged on the top panel 103. Moreover the feeding apparatus 100 includes three first holding heads 115 and a single second holding head 116. The three first holding heads 115 are connected to the XYZ transferring mechanism 109. The second holding head 116 is connected to the XY transferring mechanism 111.

The first board holder 107 is provided on the top panel 103 and at the first end 105 side. The XYZ transferring mechanism 109 is provided on the base 101 and at the first end 105 side. The XYZ transferring mechanism 109 includes an XY stage mechanism 118 and a Z stage mechanism 119. The Z stage mechanism 119 is connected to the XY stage mechanism 118. The XY stage mechanism 118 is capable of transferring the Z stage mechanism 119 in the X and Y directions between the rough center of the base 101 and the position at which the Z stage mechanism 119 faces the first board holder 107.

The three first holding heads 115 are connected to the Z stage mechanism 119. The three first holding heads 115 are arrayed in the Y direction. The Z stage mechanism 119 is capable of transferring the three first holding heads 115 in the Z direction. In other words, the XYZ transferring mechanism 109 operates to thereby transfer the three first holding heads 115 in the X, Y, and Z directions.

The structure of the XY stage mechanism 118 is not specifically limited. The structure of the Z stage mechanism 119 is not specifically limited. An arbitrary drive mechanism such as a ball-screw-driven mechanism or a belt-driven mechanism may be used for example. Moreover arbitrary members such as a guide rail or an air cylinder may be used arbitrarily. The same applies to the specific structure of the XY transferring mechanism 111 and the specific structure of the Z transferring mechanism 110.

The XY transferring mechanism 111 includes an XY stage mechanism 120. The XY stage mechanism 120 is provided on the top panel 103. The XY stage mechanism 120 extends from the position, at which the XY stage mechanism 120 faces the XY stage mechanism 118 arranged on the base 101, to the end of the top panel 103 at the second end 106 side. As a result, as shown in FIGS. 3A-B, part of the XY stage mechanism 118 at the second end 106 side faces part of the XY stage mechanism 120 at the first end 105 side in the Z direction. The XY stage mechanism 120 is capable of transferring the second holding head 116 in the X and Y directions.

The Z transferring mechanism 110 includes a Z stage mechanism 121. The Z stage mechanism 121 is provided on the base 101 and at the second end 106 side. The Z stage mechanism 121 faces part of the XY stage mechanism 120, which is arranged on the top panel 103, at the second end 106 side. The Z stage mechanism 121 includes the second board holder 108. The target board 20 is arranged on the second board holder 108. The Z stage mechanism 121 is capable of transferring the target board 20 in the Z direction.

In this embodiment, the XYZ transferring mechanism 109 corresponds to a driver configured to transfer the first holding heads 115 and to cause the first holding heads 115 to hold objects. The XY transferring mechanism 111 corresponds to a driver configured to transfer the second holding heads 116 and to cause the second holding heads 116 to hold objects.

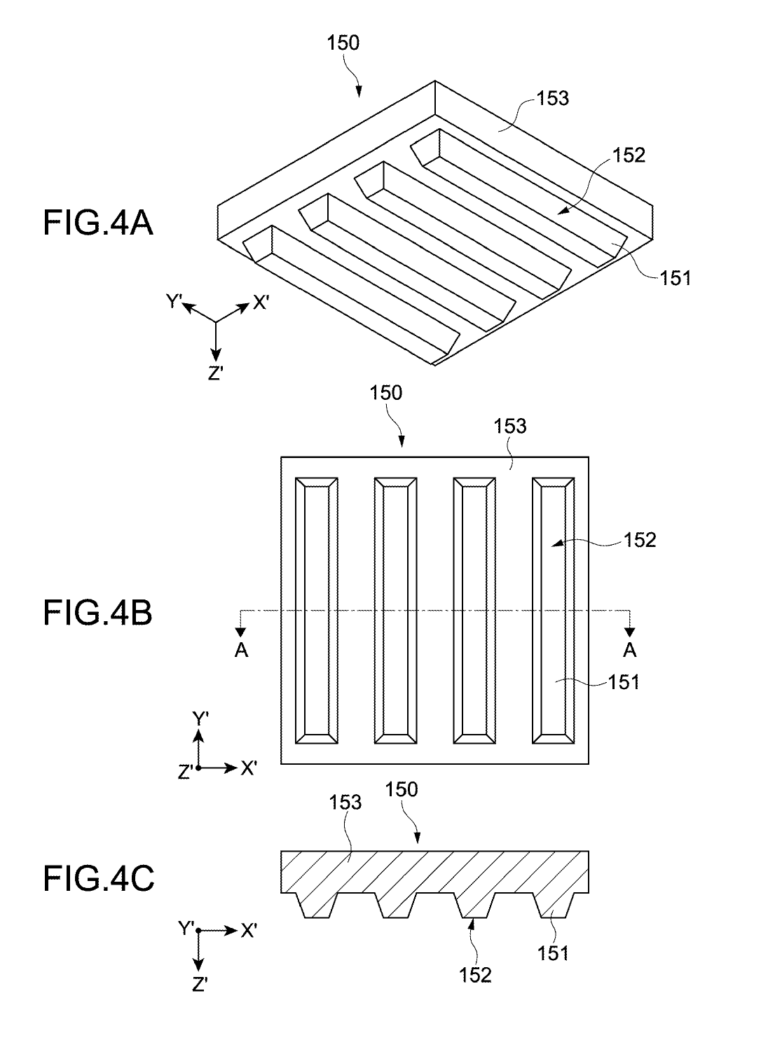

FIGS. 4A-C are diagrams schematically showing an example of the structure of a holding head 150 the present technology. FIG. 4A is a perspective view, FIG. 4B is a front view, and FIG. 4C is a cross-sectional view along the line A-A. The structure of the holding head 150 illustrated in FIGS. 4A-C is arbitrarily modified, which is used as each of the first and second holding heads 115 and 116 of FIGS. 3A-B.

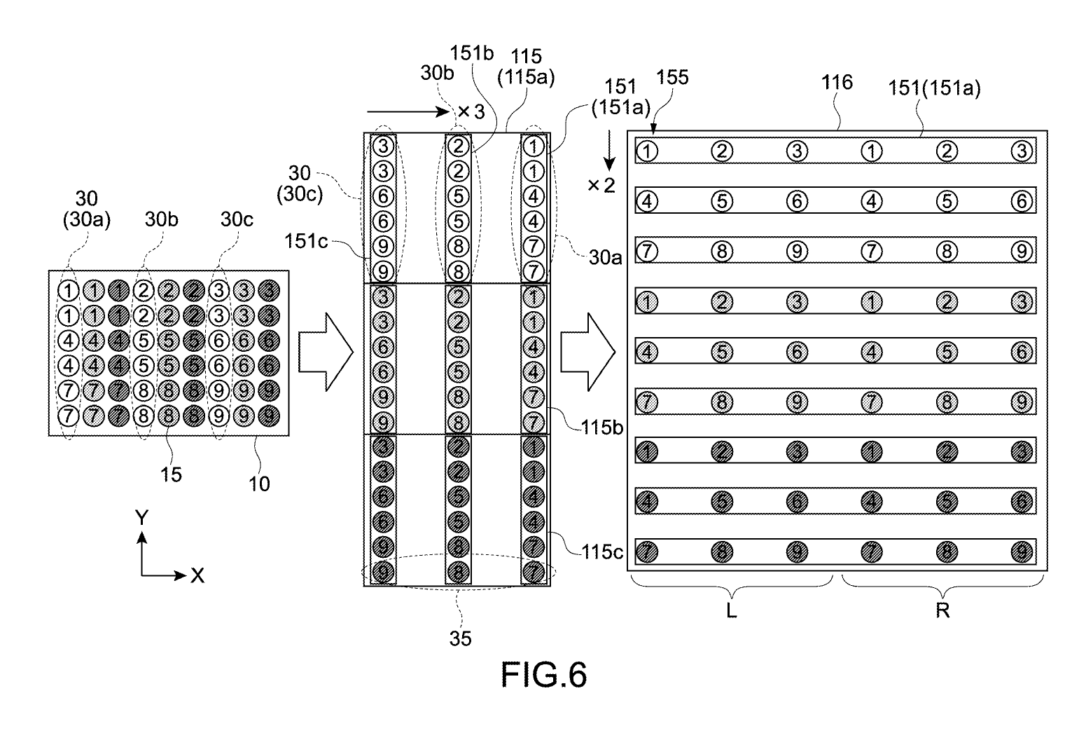

The holding head 150 includes a holder unit 152 and a support 153. The holder unit 152 includes a plurality of holders 151. The support 153 supports the holder unit 152. The plurality of holders 151 extend in a predetermined direction (Y′ direction). The plurality of holders 151 are capable of holding component groups (object groups) 30 (see FIG. 6), respectively. Each component group (object group) 30 includes a plurality of components 15 arrayed in series in the Y′ direction out of the plurality of components 15 arranged two-dimensionally. Moreover the plurality of holders 151 are arrayed in the X′ direction at predetermined pitches. The X′ direction is different from the Y′ direction.

As shown in FIGS. 4A-C, the plurality of holders 151 protrude in the Z′ direction. The Z′ direction is perpendicular to the X′ and Y′ directions. With this structure, the plurality of holders 151 are capable of holding the components 15 reliably. Moreover the X′ direction is perpendicular to the Y′ direction. With this structure, the fed components 15 are arrayed on the target board 20 in two directions perpendicular to each other. Note that the extending direction of the holders 151 is not necessarily perpendicular to the array direction of the holders 151.

The number of the plurality of holders 151, the width of the holder 151 (dimension in the X′ direction), the length of the holder 151 in the extending direction (dimension in the Y′ direction), the height of the holder 151 (dimension in the Z′ direction), the pitch between the plurality of holders 151, and the like are not limited. They may be designed arbitrarily based on the number, size, pitch, and the like of objects to be fed. For example the pitch between the plurality of holders 151 is about 10 μm to 10,000 μm. Moreover the height is about one-tenth to twice as large as the width.

In this embodiment, as shown in FIGS. 3A-B and FIG. 6, the first holding heads 115 and the second holding head 116 are structured as follows. Note that in this embodiment, the plurality of holders 151 of the first holding head 115 correspond to a plurality of first holders. Moreover in this embodiment, the plurality of holders 151 of the second holding head 116 correspond to a plurality of second holders. Hereinafter the plurality of holders 151 of the first holding head 115 will be sometimes referred to as a plurality of first holders, and the plurality of holders 151 of the second holding head 116 will be sometimes referred to as a plurality of second holders.

The first holding heads 115

The number of the holders: three

The width of the holder: approximately the same as the diameter of the component 15

The length of the holder: the dimension with which the holder is capable of holding the six components 15 arrayed in series at the pitches P1 simultaneously

The pitch between the holders: approximately the same as the pitch between the components 15 arrayed in series at the pitches P3

Note that the pitch between the holders corresponds to a first pitch. Hereinafter the pitch between the holders will be sometimes referred to as a first pitch.

The second holding head 116

The number of the holders: nine

The width of the holder: approximately the same as the diameter of the component 15

The length of the holder: the dimension with which the holder is capable of holding the six components 15 arrayed in series at the pitches P3 simultaneously

The pitch between the holders: approximately the same as the pitch between the components 15 arrayed in series at the pitches P2

Note that the pitch between the holders corresponds to a second pitch. Hereinafter the pitch between the holders will be sometimes referred to as a second pitch.

Three first holding heads 115 structured as described above are arranged. The holders 151 of the arranged three first holding heads 115 extend in the Y direction (first direction). With this structure, each holder 151 of the first holding heads 115 holds a component group 30 out of the plurality of components 15 arranged two-dimensionally. Each component group 30 includes a plurality of components 15 arrayed in series in the Y direction.

A single second holding head 116 is used. The holders 151 of the second holding head 116 extend in the X direction (second direction). With this structure, each holder 151 of the second holding head 116 is capable of holding a component group 35 out of the plurality of components 15 arranged two-dimensionally (see FIG. 6). Each component group 35 includes a plurality of components 15 arrayed in series in the X direction.

Each of the plurality of holders 151 holds the components 15 by using adhesive power. The adhesive power is higher than the holding power of the original board 10, which holds the components 15.

The following is an example of a method of manufacturing the holding head 150 including the holders 151. Firstly, a molding die is manufactured by using a photolithography equipment. In other words, a resist is applied to a quartz board or the like. The quartz board is irradiated with ultraviolet with a mask interposed therebetween. Then the quartz board is developed. As a result, a molding die having a concavo-convex pattern is manufactured. The concavo-convex pattern corresponds to the plurality of holders 151 of FIGS. 4A-C and the like.

When the holding head 150 is manufactured by using a molding die, a release film is applied to a molding die having a concavo-convex pattern. A release film made of fluoropolymer such as Novec (3M Japan Limited) or Nanos (T&K Inc.) is used, for example. A tackifier resin (for example silicone resin, fluororesin, urethane resin, or the like) is poured into the molding die. A board (for example, stainless steel, glass, synthetic quartz, or the like) as the support 153 is stuck to the tackifier resin. Then the board as the support 153 stuck to the tackifier resin is removed from the molding die. As a result, the adhesive holding head 150 is manufactured. Note that the tackifier resin is thermally cured or ultraviolet cured, for example. Moreover Young's modulus, i.e., the physical property, of the cured tackifier resin is about 0.5 MPa to 5 MPa. Young's modulus of the cured tackifier resin may not be 0.5 MPa to 5 MPa.

When manufacturing a molding die by using a photolithography equipment, it is easier to form groove patterns extending in one direction than to form many hole patterns. Moreover if foreign particles and the like are attached to the walls of the holes of the molding die having the hole patterns, it is difficult to remove the foreign particles from the holes. Meanwhile, if foreign particles and the like are attached to the walls of the grooves of the molding die having the groove patterns, it is relatively easy to remove the foreign particles from the grooves by spraying clean air, by flushing the foreign particles with an organic solvent etc., or the like.

Moreover if applying a release film by immersing a molding die in liquid, it is easier to apply a release film to the molding die having the groove patterns than to the molding die having the hole patterns because the liquid is spread in the grooves with ease. Moreover when pouring a tackifier resin into the molding die to form the holders 151, air is likely to be entrapped in the hole patterns but not in the groove patterns, which is advantageous.

The above-mentioned molding die having the groove patterns is used to manufacture the holding head 150 of this embodiment. It is therefore possible to manufacture the molding die and the holding head 150 with ease with a high degree of accuracy.

The holding head 150 of the present technology is also advantageous from the viewpoint of release resistance. Release resistance of a holding head configured to hold components is high because of the adhesive power of a tackifier resin. The larger the surface area of the tackifier resin, it is more difficult to release the tackifier resin. If it is difficult to release the tackifier resin, the tackifier resin may be broken depending on the mechanical strength of the tackifier resin when releasing the tackifier resin. The tackifier resin may remain in the concaves of the molding die. As a result, desired convexes may not be formed.

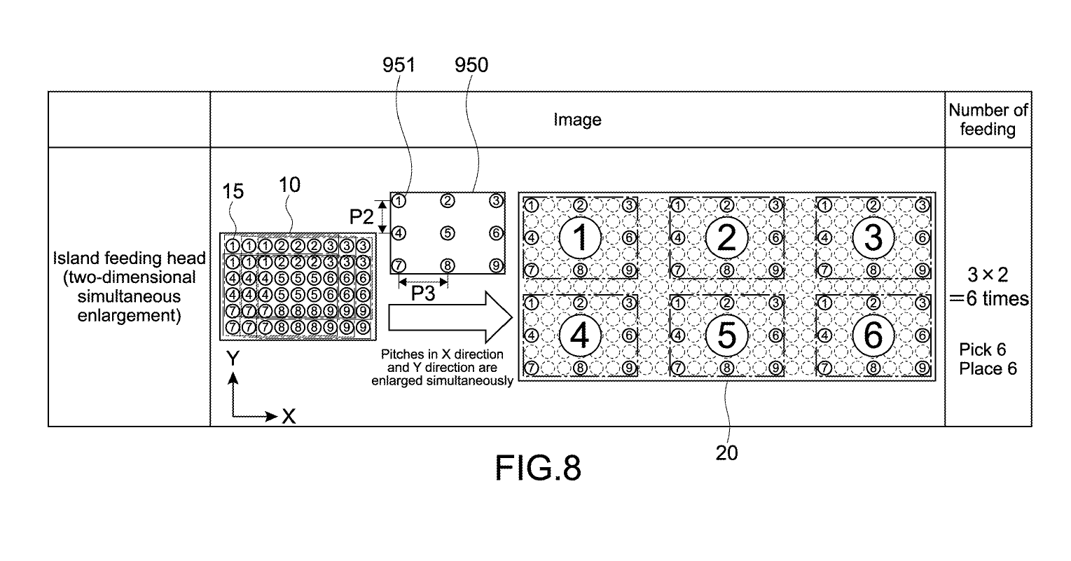

In a comparative example, a holding head 950 including island holding convexes 951 is formed by using a molding die having hole patterns (see holding head 950 of FIG. 8). It is easier to form the holding head 150 of the present technology including the linear holders 151 extending in one direction than to form the holding head 950 including the island holding convexes 951 arrayed as described above. The reason is as follows. Release resistance of the linear holders 151 is lower than release resistance of the island holding convexes 951 because the surface area of the linear holders 151 is smaller than the surface area of the island holding convexes 951. In addition, the mechanical strength of the larger holders 151 is higher than the mechanical strength of the smaller holding convexes 951. So the holders 151 are not likely to be broken when releasing the holders 151 from the molding die.

Moreover if foreign particles and the like are attached to the holding convexes 951 of the holding head 950 and to the gaps between the holding convexes 951, it is difficult to remove the foreign particles therefrom. Meanwhile, even if foreign particles and the like are attached to the linear holders 151 of the holding head 150 and to the gaps between the linear holders 151, it is relatively easy to remove the foreign particles therefrom by spraying clean air, by flushing the foreign particles with an organic solvent etc., or the like.

Moreover when the holding head 950 including the island holding convexes 951 is pushed against the original board 10 or the target board 20, the holding convexes 951 are likely to be deformed. The components 15 are therefore likely to be misaligned. To the contrary, the mechanical strength of the linear holders 151 is higher than the mechanical strength of the island holding convexes 951. When the holding head 150 is pushed against the original board 10 or the target board 20, the holders 151 are less deformed than the island holding convexes 951 are. The components 15 are therefore not likely to be misaligned. The higher mechanical strength contributes to higher durability of the holding head 150. The holding head 150 including the linear holders 151 therefore has a tolerance for a larger number of feeding. Moreover the cost for the materials of the holding head 150 of the present technology can be lower than the cost for the materials of the holding head 950 including the island holding convexes 951.

As shown in FIG. 4C, the cross-sectional shape of each of the plurality of holders 151 of this embodiment seen in the extending direction of the holders 151 is substantially trapezoidal, where the long side is the support 153 side and the short side is the side in contact with the components 15. With this structure, it is much easier to release the holders 151 from the molding die. Moreover if foreign particles and the like are attached to the linear holders 151, it is much easier to remove the foreign particles therefrom. In other words, it is easy to wash the holding head 150. Note that the shape of the holder 151 seen in the width direction may also be substantially trapezoidal.

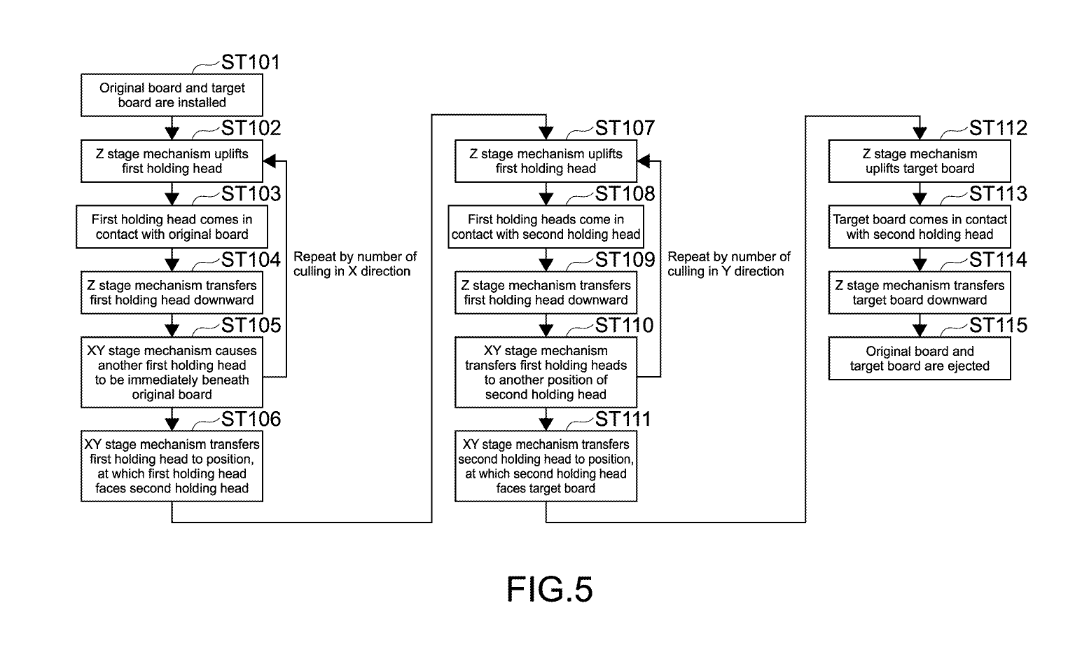

FIG. 5 is a flowchart showing an example of the behavior of the feeding apparatus 100 of this embodiment. FIG. 6 is a diagram schematically illustrating the steps of FIG. 5. As shown in FIG. 6, each component group 30 includes six components 15 arrayed in series in the Y direction out of the plurality of components 15 arranged on the original board 10.

Firstly, the original board 10 is mounted on the first board holder 107, and the target board 20 is mounted on the second board holder 108 (Step 101). The XYZ transferring mechanism 109 transfers one of the three first holding heads 115 to a predetermined position, at which the first holding heads 115 face the original board 10.

In this embodiment, as shown in FIG. 6, a first holding head 115a is the uppermost holding head (end side in the Y direction). The first holding head 115a is transferred to a predetermined position. The first holding head 115a includes three holders 151 including a holder 151a at the end. The holder 151a is transferred to the position, at which the holder 151a faces a component group 30a. The component group 30a is at the end of the original board 10. In this case, the other holders 151b and 151c of the first holding head 115 face component groups 30b and 30c, respectively. The pitch between the component group 30a and the component group 30b is the pitch P3, and the pitch between the component group 30b and the component group 30c is the pitch P3. As shown in FIG. 6, the three holders 151a to 151c of the first holding head 115a therefore face the uncolored (white) component groups 30a to 30c, respectively.

In this situation, the Z stage mechanism 119 of the XYZ transferring mechanism 109 transfers the first holding head 115a toward the original board 10 (Step 102). In this case, the other first holding heads 115b and 115c are uplifted together with the first holding head 115a. As a matter of course, only the first holding head 115a may be uplifted.

The first holding head 115a comes in contact with the original board 10 (Step 103). Specifically, the three holders 151a to 151c face and come in contact with the three component groups 30a to 30c, respectively. As shown in FIG. 6, the three holders 151a to 151c therefore hold the three component groups 30a to 30c, respectively. Note that FIG. 6 shows the front view of the first holding head 115a, which holds the components 15. In other words, the positions of the component groups 30 on the original board 10 are reversed in the horizontal direction (X direction), and are therefore different from the positions of the component groups 30 on the three holders 151 in the horizontal direction (X direction).

As described above, in this embodiment, the first holding head 115 holds the three component groups 30a to 30c out of the component groups 30 arrayed in series in the Y direction at the pitches P1. Two component groups are interposed between the component groups 30a and 30b, and two component groups are interposed between the component groups 30b and 30c. In other words, in this embodiment, a plurality of component groups 30 are culled. In other words, cull-feeding (skip-feeding) is performed. In this embodiment, the cull-pitch (skip-pitch) is two.

The Z stage mechanism 119 transfers the first holding head 115 downward (Step 104). As described above, the adhesive power of the holders 151 is higher than the adhesive power of the original board 10. The three holders 151 therefore hold the three component groups 30, respectively.

The XY stage mechanism 118 of the XYZ transferring mechanism 109 causes another first holding head 115 to be immediately beneath the original board 10 (Step 105). In this embodiment, as shown in FIG. 6, the XY stage mechanism 118 transfers the first holding head 115b, which is at the middle, to a predetermined position. The first holding head 115b is transferred to the position, at which the three holders 151 face the three light-gray component groups 30, respectively. In this situation, Steps 102 to 105 are repeatedly performed.

In Step 105 for the second time, as shown in FIG. 6, the lowermost first holding head 115c is transferred to a predetermined position. The first holding head 115c is transferred to the position, at which the three holders 151 face the three dark-gray component groups 30, respectively. In this situation, Steps 102 to 105 are repeatedly performed. As a result, the three first holding heads 115 hold all the plurality of components 15 arranged on the original board 10.

The number of performing Steps 102 to 105 repeatedly to hold all the components 15 relates to the number of the cull-pitches. In this embodiment, since the number of the cull-pitches is two, it is necessary to hold the skipped component groups 30 twice additionally. In other words, it is necessary to hold the component groups 30 three times in total. Moreover the enlargement factor of the pitches relates to the number of the cull-pitches. Because the enlargement factor of the pitch corresponds to the skipped component groups 30, the enlargement factor of the pitch P3 is three. The following formulae show those relationships. The necessary number of holding=the number of cull-pitches+1. The enlargement factor=the number of cull-pitches+1.

Hereinafter, the component groups 30 held by the first holding heads 115 will be referred to as the first component groups 30 (denoted by same reference numeral). As shown in FIG. 6, in this embodiment, when the three first holding heads 115 are fixed, the three first component groups 30 held by the first holding heads 115 are arrayed in series in the Y direction (first direction).

The XY stage mechanism 118 of the XYZ transferring mechanism 109 transfers the first holding heads 115 to a predetermined position, at which the first holding heads 115 face the second holding head 116 (Step 106). The three first holding heads 115 are transferred to the position, at which the three first holding heads 115 face a half-area L of the second holding head 116. The half-area L is a half of the second holding head 116 in the X direction. As shown in FIG. 6, when the first holding heads 115 are transferred, a component 15 (white component denoted by No. 1) at the upper-right end of the first holding heads 115 faces the left end 155 of the uppermost holder 151a of the second holding head 116.

The Z stage mechanism 119 of the XYZ transferring mechanism 109 transfers the three first holding heads 115 toward the second holding head 116 (Step 107). Then the three first holding heads 115 come in contact with the second holding head 116 (Step 108). The holders 151 of the second holding head 116 therefore hold a plurality of component groups 35 arrayed in series in the X direction at the pitches P3 (arrayed in series at first pitches) out of the plurality of components 15 held by the first holding heads 115.

The Z stage mechanism 119 transfers the first holding heads 115 downward (Step 109). In this embodiment, the adhesive power of the second holders 151 of the second holding head 116 is higher than the adhesive power of the first holders 151 of the first holding heads 115. The second holders 151 therefore hold a plurality of components 15.

As described above, in this embodiment, the second holding head 116 holds the plurality of components 15 held by the first holding heads 115. The second holding head 116 holds a plurality of second component groups 35 (denoted by same reference numeral). Each second component group 35 includes a plurality of components 15 arrayed in series in the X direction at the pitches P3 out of the plurality of components 15 held by the first holding heads 115. As shown in FIG. 6, the cull-pitch is one when the second holding head 116 holds the plurality of component groups 35. The necessary number of holding is therefore two, and the enlargement factor of the pitch is also two.

The XY stage mechanism 118 transfers the first holding heads 115 to another position of the second holding head 116 (Step 110). When the three first holding heads 115 are transferred, the three first holding heads 115 face the other half-area R of the second holding head 116. Then Steps 107 to 110 are performed repeatedly. As a result, the second holders 151 of the second holding head 116 hold all the plurality of components 15 held by the three first holding heads 115.

The XY stage mechanism 120 of the XY transferring mechanism 111 transfers the second holding head 116 to a predetermined position at which the second holding head 116 faces the target board 20 (Step 111). Then the Z stage mechanism 121 of the Z transferring mechanism 110 transfers the target board 20 toward the second holding head 116 (Step 112). The target board 20 comes in contact with the second holding head 116 (Step 113). After that the Z stage mechanism 121 transfers the target board 20 downward (Step 114).

In this embodiment, the adhesive power of the second holders 151 of the second holding head 116 is higher than the adhesive power of the target board 20. As a result, the target board 20 holds all the plurality of components 15 held by the second holding head 116. As a result, the plurality of components 15 arranged on the original board 10 are fed to the target board 20, where the pitches in the X direction and the Y direction are enlarged (see FIG. 2).

The original board 10 and the target board 20 are ejected. The feeding apparatus 100 finishes feeding the components (Step 115). Note that the original board 10 may be ejected from the feeding apparatus 100 before the target board 20 is ejected at a time when the first holding heads 115 hold the plurality of components 15.

In the feeding example of FIG. 5, the three first holding heads 115 pick up (stick to) a plurality of components 15 three times, and never place (put) the components 15. Moreover the second holding head 116 picks up the plurality of components 15 twice, and places the plurality of components 15 once. In other words, the number of feeding in total is five pick-up operations and one placing operation. Note that if the number of feeding is equal to the number of the pick-up operation, the number of feeding is five.

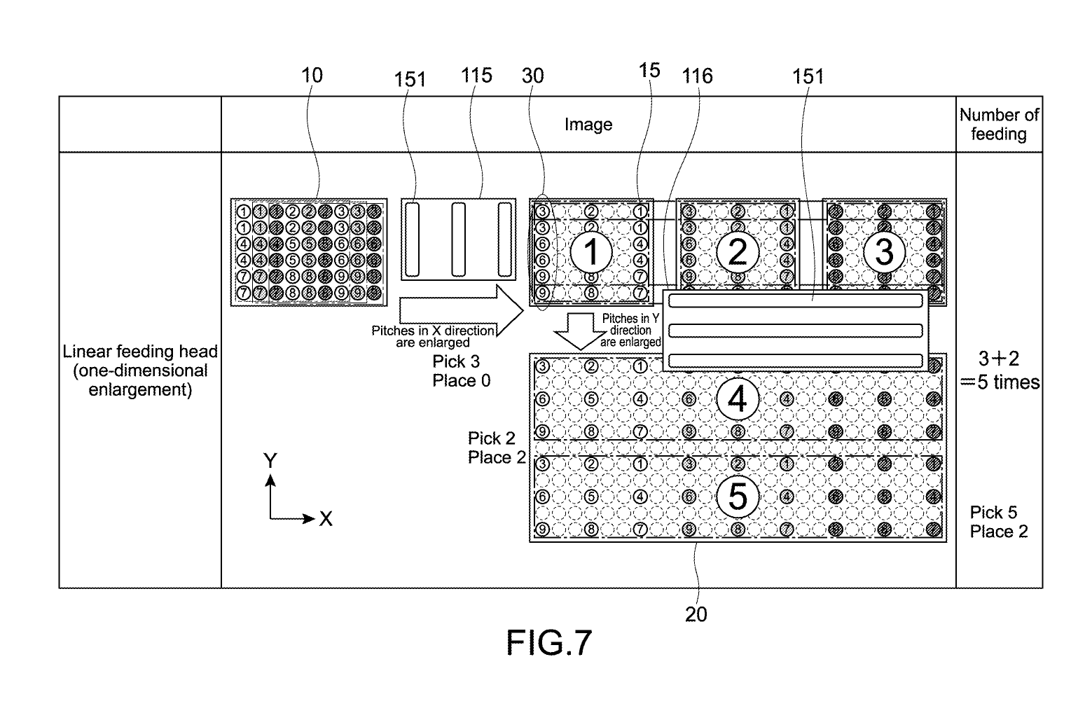

FIG. 7 is a diagram schematically showing a modification example of the component-feeding technology of this embodiment. In FIG. 7, the “linear feeding head” means the holding head 150 including the linear holders 151. Moreover the “one-dimensional enlargement” means that the pitches in the X direction and the Y direction are enlarged by each direction.

In this component-feeding technology, the first holding heads 115 are fixed such that the three first component groups 30 held by the first holding heads 115 are arrayed in series in the X direction (second direction) at first pitches. Then the second holding head 116 holds the plurality of components 15 held by the three first holding heads 115. The structure of the second holding head 116 is as follows.

The second holding head 116

The number of the holders: three

The width of the holder: approximately the same as the diameter of the component 15

The length of the holder: the dimension with which the holder is capable of holding the nine components 15 arrayed in series at the pitches P3 simultaneously

The pitch between the holders: approximately the same as the pitch between the components 15 arrayed in series at the pitches P2

Note that FIG. 7 illustrates the first and second holding heads 115 and 116 smaller in size.

As shown in FIG. 7, the first and second holding heads 115 and 116 having such structures may feed components, for example. Also according to this component-feeding technology, the plurality of components 15 arranged on the original board 10 are fed to the target board 20, where the pitches in the X direction and the Y direction are enlarged.

In the feeding example of FIG. 7, the three first holding heads 115 pick up the plurality of components 15 three times, and never place the components 15. Moreover the second holding head 116 picks up the plurality of components 15 twice, and places the plurality of components 15 twice. In other words, the number of feeding in total is five pick-up operations and two placing operations. Note that if the number of feeding is equal to the number of the pick-up operation, the number of feeding is five.

FIG. 8 is a diagram schematically illustrating a component-feeding technology of a comparative example. In FIG. 8, the “island feeding head” means the holding head 950 including the island holding convexes 951. Moreover the “two-dimensional simultaneous enlargement” means that the pitches in the X direction and the Y direction are enlarged simultaneously.

According to this component-feeding technology, the single holding head 950 including the island holding convexes 951 is used. The holding head 950 includes the nine holding convexes 951 in total, including three holding convexes 951 arrayed in the X direction and three holding convexes 951 arrayed in the Y direction. The pitch between the holding convexes 951 in the X direction is the pitch P3, and the pitch between the holding convexes 951 in the Y direction is the pitch P2. Moreover each holding convex 951 is capable of holding one component 15. In other words, the nine holding convexes 951 hold nine components 15 in one holding operation.

As shown in FIG. 8, according to this component-feeding technology, the holding head 950 picks up the components 15. Then the holding head 950, which holds the components 15, is transferred to a predetermined position on the target board 20. Then the holding head 950 places the components 15 on the target board 20. In order to feed all the components on the original board 10, the pick-up positions are changed again and again, and the components 15 are picked up six times. Accordingly, the components 15 are placed on the target board 20 six times. The number of this operation is equal to the number of feeding. Note that if the number of feeding is equal to the number of the pick-up operation, the number of feeding is six.

As described above, according to the present component-feeding technology of FIGS. 4A-C and FIG. 7, the number of feeding is less than the number of feeding of the component-feeding technology of the comparative example.

As described above, the feeding apparatus 100 of this embodiment includes the first holding heads 115 and the second holding head 116. Each first holding head 115 includes the plurality of first holders 151 extending in the Y direction and arrayed in the X direction at the first pitches. The second holding head 116 includes the plurality of second holders 151 extending in the X direction and arrayed in the Y direction at the second pitches. The first holders 151 extending in the Y direction are capable of holding the plurality of components 15 arrayed in series in the Y direction. Moreover the second holders 151 extending in the X direction are capable of holding the plurality of components 15 arrayed in series in the X direction. As a result, the number of feeding can be reduced. In other words, it is possible to feed the plurality of components 15 with the less number of feeding such that the components 15 are arrayed in the X direction at the first pitches and arrayed in the Y direction at the second pitches. Moreover the first and second holding heads 115 and 116 have the linear holders 151 and therefore have simple structures.

The following methods are examples of a method of selectively culling many components arranged on a plane regularly and feeding them to a target board. According to one method, a feeding head including many vacuum nozzles vacuum-contacts and feeds components. According to another feeding method, electrostatic attractive force is used. According to another feeding method, if components to be fed are magnetic materials, magnetic force is generated and reduced. Moreover as described in the feeding method of this embodiment, components are attached to the feeding heads, the feeding heads pick up the attached components, and the feeding heads deliver the components to the target board. Here, the adhesive power of the feeding heads is higher than the adhesive power of the original board, and the adhesive power of target board is higher than the adhesive power of the feeding heads.

If a component to be fed is as small as several tens of μm or less, it is difficult to manufacture vacuum-contact-type vacuum nozzles. Moreover vacuum holes are likely to be clogged with foreign particles. Such vacuum holes require troublesome maintenance. In a feeding method using electrostatic attractive force, it is difficult to provide minute electrodes for feeding heads. In a feeding method using magnetic force, it is difficult to selectively pick up only components to be fed because of wide magnetic field lines.

To the contrary, according to the feeding method using adhesive power, minute concavo-convex shape can be manufactured relatively easily by molding a resin or the like. In addition, even if minute foreign particles are attached to the holding head, it is easy to wash the holding head. So the holding head requires easy maintenance. From this viewpoint, the present technology using adhesive power is good at feeding minute components.

A feeding head having a minute concavo-convex shape is used to cull-feeding using adhesive power. One method of manufacturing such a feeding head is molding. In this case, the more minute the concavo-convex shape, it is more difficult to manufacture a molding die. Moreover the mechanical strength of convexes of a molded feeding head is low. Because of this, when the convexes are pushed against an original board or a target board, the convexes may be deformed and position accuracy of components may be decreased, which are problematic. Moreover the release resistance of a feeding head is increased after resin is cured in order to obtain a feeding head having high adhesive power. It is therefore difficult to remove the feeding head from a molding die. Moreover the larger the number of components to be fed all at once, the larger the number of the convexes of a feeding head. The larger the number of the convexes, the larger the total surface area and the higher the release resistance when molding the feeding head. It is therefore difficult to mold such a feeding head.

As described above, in this embodiment, the linear holders 151, which extend in one direction, are formed. Those problems may therefore be solved. Moreover the number of feeding will be described. The larger the cull-pitch, the much larger the number of feeding necessary for the holding head 950 including the island holding convexes 951 to feed the same number of components in the end. To the contrary, the number of feeding by the holding head 150 of the present technology can be smaller.

### Second Embodiment

A feeding apparatus according to a second embodiment of the present technology will be described. Hereinafter, description of the structures and behaviors similar to the structures and behaviors of the feeding apparatus 100 of the above-mentioned embodiment will be omitted or simplified.

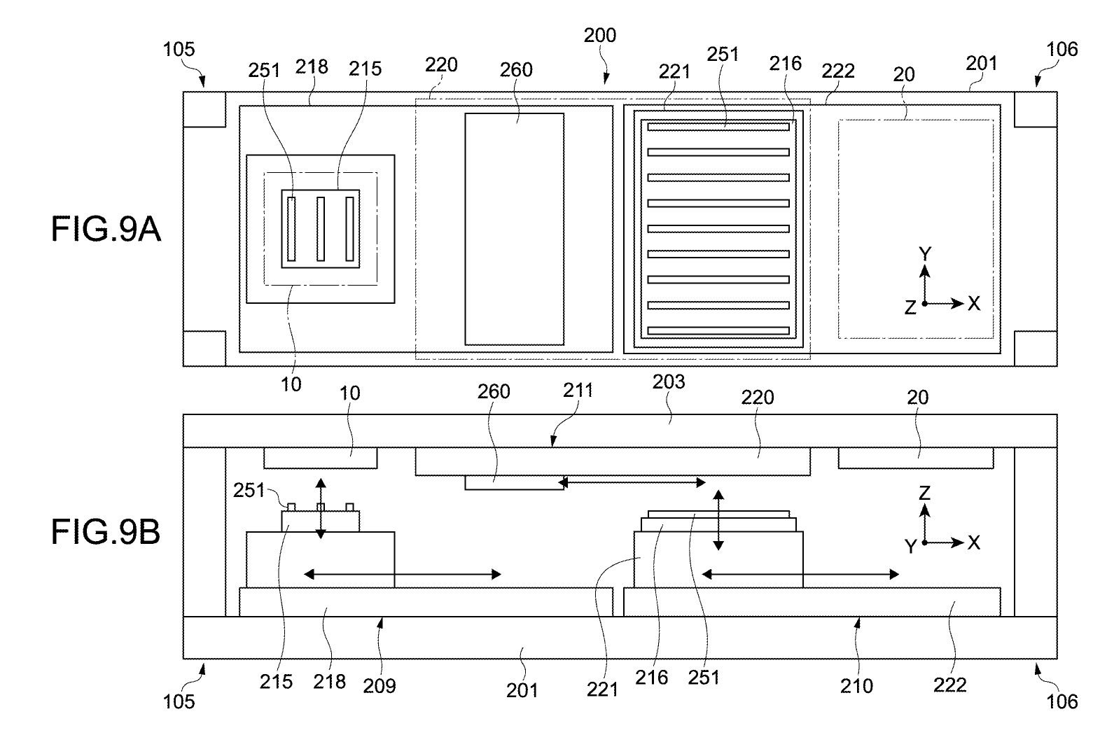

FIGS. 9A-B are diagrams schematically showing an example of the structure of a feeding apparatus according to a second embodiment of the present technology. A feeding apparatus 200 includes one first holding head 215 and one second holding head 216. The structures of the first and second holding heads 215 and 216 are similar to the structures of the first and second holding heads of the first embodiment of FIG. 6. The first holding head 215 includes holders 251 extending in the Y direction. The second holding head 216 includes holders 251 extending in the X direction.

Moreover the feeding apparatus 200 includes a medium board 260, i.e., a mount. The plurality of first component groups 30 held by the first holding head 215 are mounted on the medium board 260. In other words, in this embodiment, the plurality of components 15 are fed from the original board 10 to the first holding head 215, to the medium board 260, to the second holding head 216, and to the target board 20 in order. Differences between the adhesive powers of those members help to deliver the plurality of components 15.

As shown in FIGS. 9A-B, the original board 10, an XY transferring mechanism 211, and the target board 20 are arranged on a top panel 203 in this order from the first end 105 to the second end 106. The medium board 260 is connected to an XY stage mechanism 220 of the XY transferring mechanism 211. Two XYZ transferring mechanisms 209 and 210 are arranged on a base 201. The XYZ transferring mechanism 209 is arranged at the first end 105 side, and the first holding head 215 is connected to the XYZ transferring mechanism 209. The XYZ transferring mechanism 210 is arranged at the second end 106 side, and the second holding head 216 is connected to the XYZ transferring mechanism 210.

The first holding head 215 can be transferred from the original board 10 to the medium board 260. The medium board 260 can be transferred from the first holding head 215 to the second holding head 216. The second holding head 216 can be transferred from the medium board 260 to the target board 20.

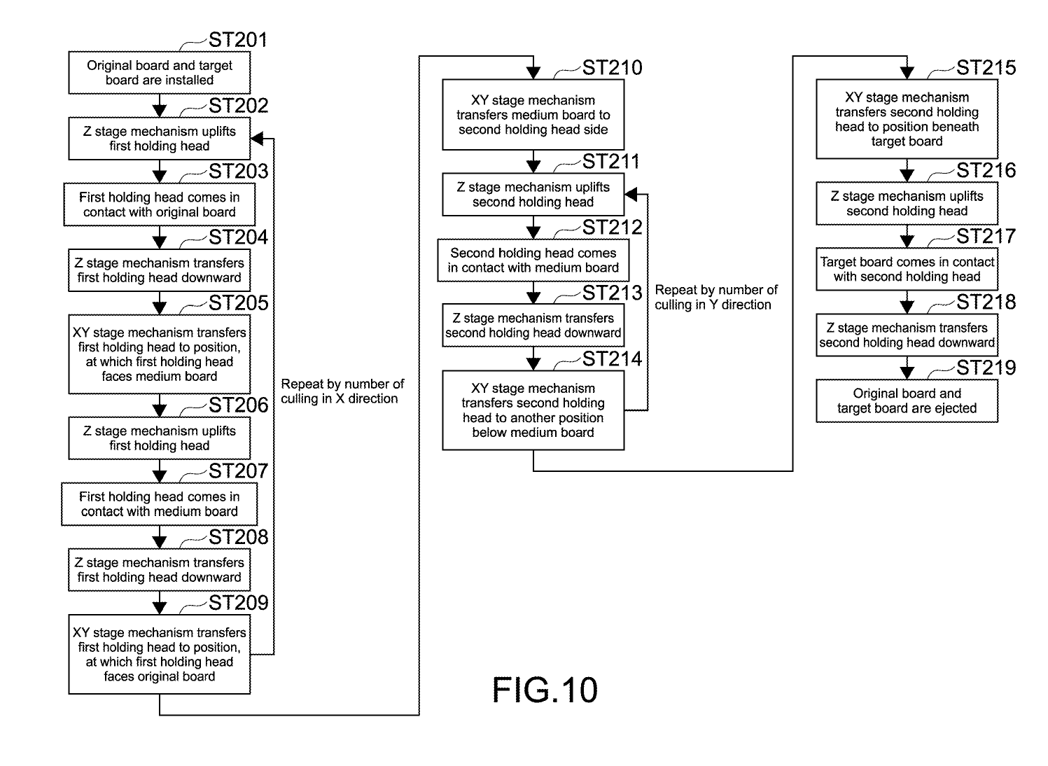

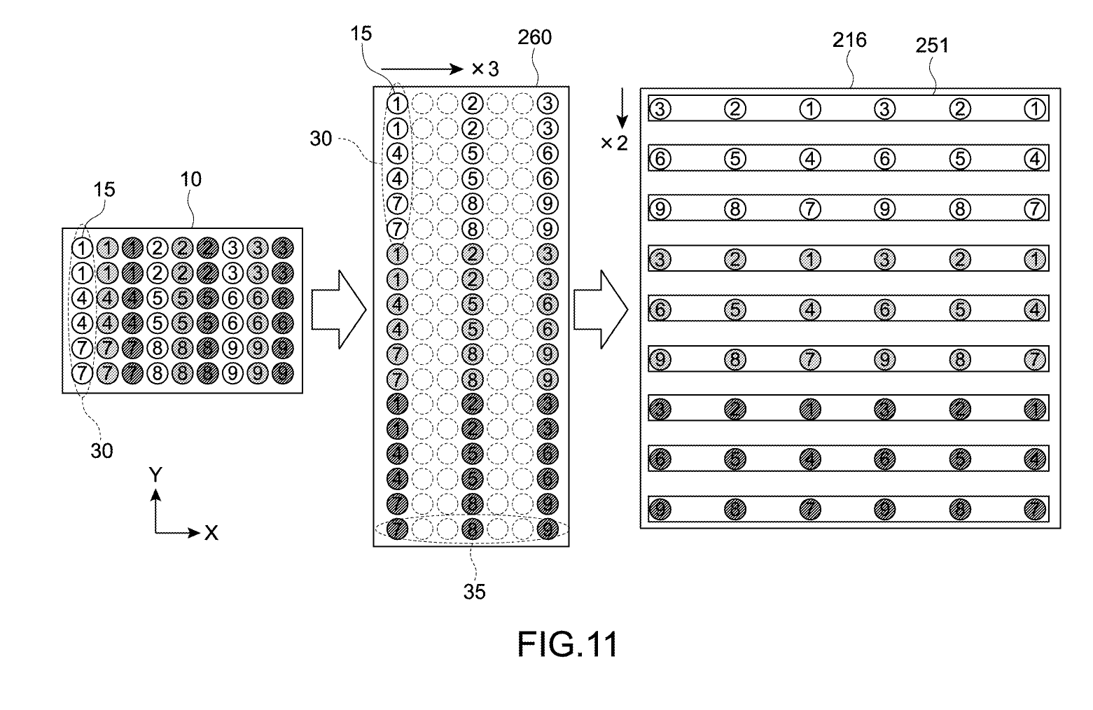

FIG. 10 is a flowchart showing an example of the behavior of the feeding apparatus 200 of this embodiment. FIG. 11 is a diagram schematically illustrating the steps of FIG. 10.

In Steps 201 to 204, the first holding head 215 holds three first component groups 30. Then an XY stage mechanism 218 transfers the first holding head 215 to a predetermined position, at which the first holding head 215 faces the medium board 260 (Step 205). In this embodiment, as shown in FIG. 11, when the first holding head 215 is transferred, the first holding head 215 faces the top area of the medium board 260. Then in Steps 206 to 208, the three first component groups 30 (three uncolored component groups 30) held by the first holding head 215 are mounted on the medium board 260.

The XY stage mechanism 218 returns the first holding head 215 to a predetermined position, at which the first holding head 215 faces the original board 10. Steps 202 to 209 are performed repeatedly by the number of culling. As a result, as shown in FIG. 11, all the plurality of components 15 arranged on the original board 10 are fed to the medium board 260. In this embodiment, the first holding head 215 holds three component groups 30 and arrays the three component groups 30 on the medium board 260 in series in the Y direction, a plurality of times.

In Steps 210 to 214, the second holding head 216 holds the plurality of components 15 held by the medium board 260. In other words, the second holding head 216 holds a plurality of second component groups 35. Each second component group 35 includes a plurality of components 15 arrayed in series in the X direction at the first pitches out of the plurality of components 15 mounted on the medium board 260.

Specifically, the XY stage mechanism 220 transfers the medium board 260 to the second holding head 216 side (Step 210). A Z stage mechanism 221 uplifts the second holding head 216 (Step 211). The second holding head 216 comes in contact with the medium board 260 (Step 212). The Z stage mechanism 221 transfers the second holding head 216 downward (Step 213). An XY stage mechanism 222 transfers the second holding head 216 to another position below the medium board 260 (Step 214). Steps 211 to 214 are performed repeatedly a predetermined number of times. As a result, as shown in FIG. 11, the second holding head 216 holds all the plurality of components 15 on the medium board 260.

The XY stage mechanism 222 transfers the second holding head 216 to the position beneath the target board 20 (Step 215). Then the plurality of components 15 are fed to the target board 20. Feeding of the components is finished (Steps 216 to 219). Also according to this component-feeding technology, the plurality of components 15 arranged on the original board 10 are fed to the target board 20, where the pitches in the X direction and the Y direction are enlarged.

In the feeding example of FIG. 10, the single first holding head 215 picks up the plurality of components 15 three times, and places the plurality of components 15 three times. Moreover the second holding head 216 picks up the plurality of components 15 twice, and places the plurality of components 15 once. In other words, the number of feeding in total is five pick-up operations and four placing operations. Note that if the number of feeding is equal to the number of the pick-up operation, the number of feeding is five.

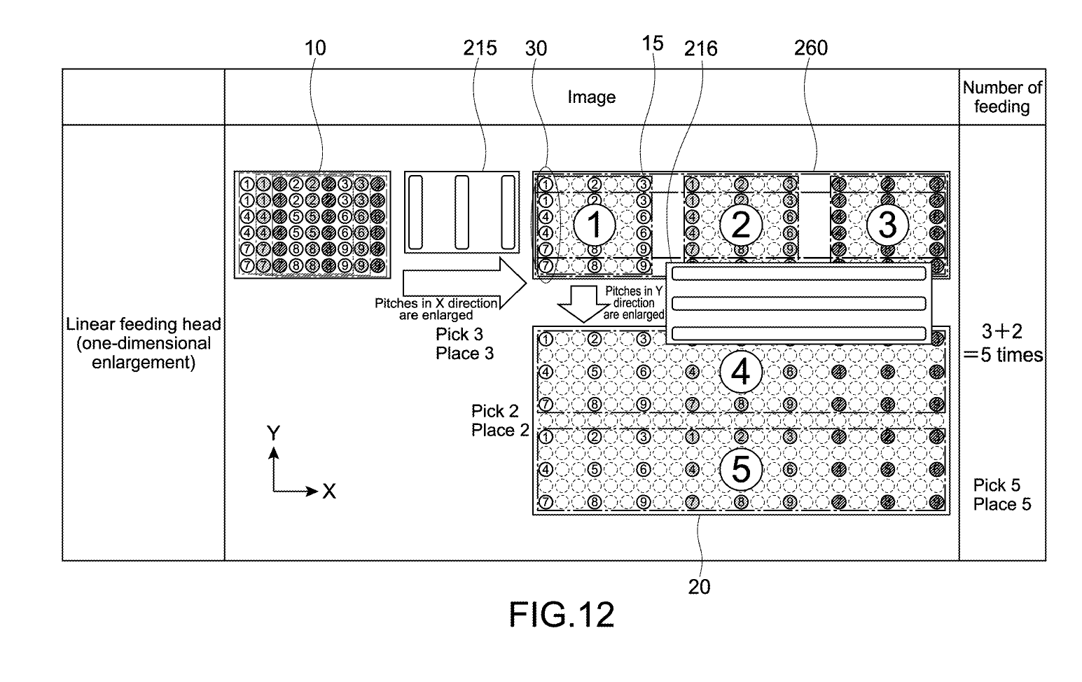

FIG. 12 is a diagram schematically showing a modification example of the component-feeding technology of this embodiment. According to this component-feeding technology, the first holding head 215 holds three first component groups 30. The three first component groups 30 held by the first holding head 215 are arrayed on the medium board 260 at the first pitches in series in the X direction. The first holding head 215 performs this operation repeatedly a plurality of times. Then the second holding head 216 holds the plurality of components 15 mounted on the medium board 260. Note that the structure of the second holding head 216 is similar to the structure of the second holding head of the first embodiment of FIG. 7. Also according to this component-feeding technology, the plurality of components 15 arranged on the original board 10 are fed to the target board 20, where the pitches in the X direction and the Y direction are enlarged.

According to the feeding example of FIG. 12, the single first holding head 215 picks up the plurality of components 15 three times, and places the plurality of components 15 three times. Moreover the second holding head 216 picks up the plurality of components 15 twice, and places the plurality of components 15 twice. In other words, the number of feeding in total is five pick-up operations and five placing operations. Note that if the number of feeding is equal to the number of the pick-up operation, the number of feeding is five.

### Third Embodiment

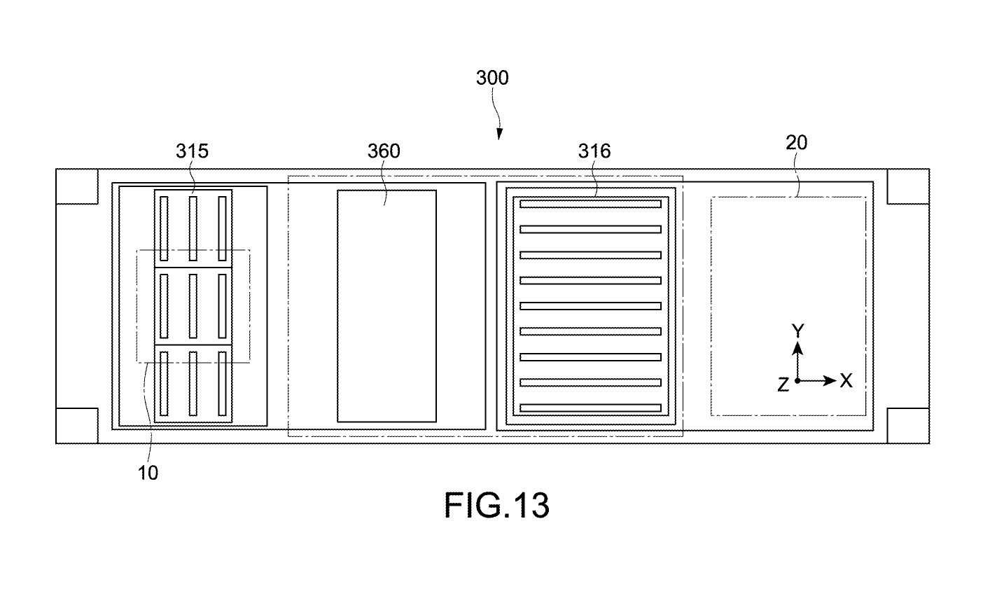

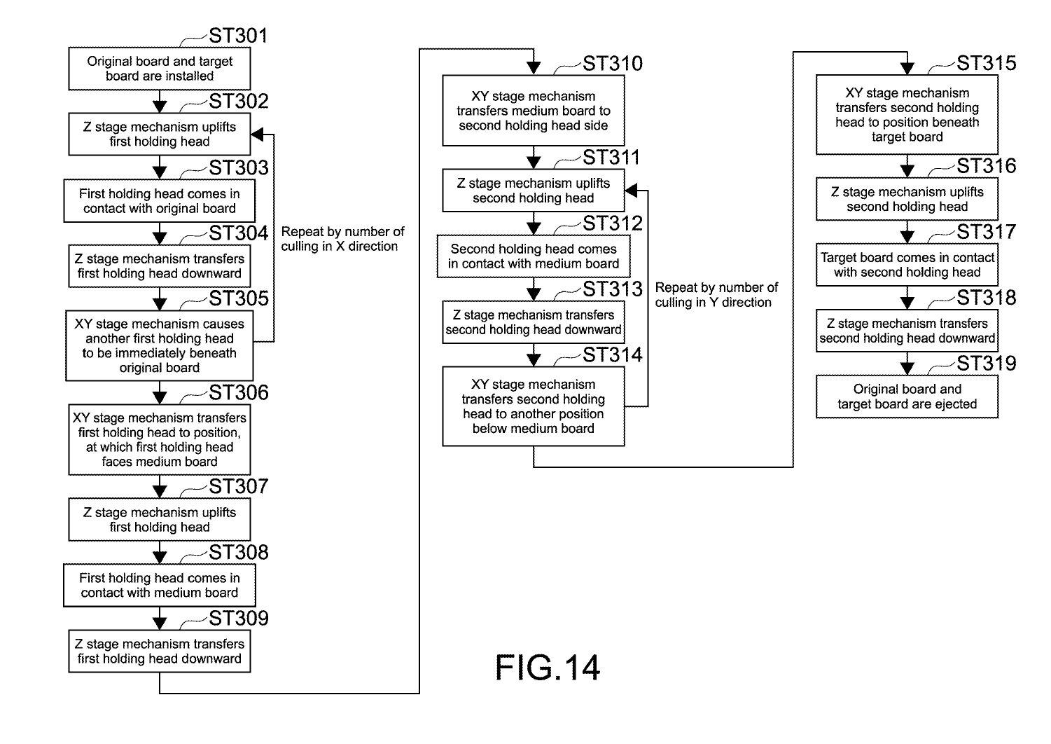

FIG. 13 is a diagram schematically showing an example of the structure of a feeding apparatus according to a third embodiment of the present technology. FIG. 14 is a flowchart showing an example of the behavior of the feeding apparatus of this embodiment.

The structure of a feeding apparatus 300 of this embodiment is similar to the structure of the feeding apparatus 200 of the second embodiment except that the feeding apparatus 300 includes three first holding heads 315. According to the second embodiment, the single first holding head 215 picks up a plurality of components 15 three times, and places a plurality of components 15 three times. As a result, all the plurality of components 15 are fed from the original board 10 to the medium board 260. In this embodiment, the three first holding heads 315 pick up a plurality of components 15 three times, and place a plurality of components 15 once. As a result, all the plurality of components 15 are fed from the original board 10 to a medium board 360.

In Steps 301 to 305 of FIG. 14, the three first holding heads 315 hold a plurality of components 15 mounted on the original board 10. In Steps 306 to 309, the plurality of components 15 held by the three first holding heads 315 are mounted on the medium board 360. Step 310 to Step 319 are similar to the above-mentioned steps of the second embodiment.

As described above, the plurality of first holding heads 315 may hold the plurality of first component groups 30, and the plurality of first component groups 30 may be arrayed on the medium board 360 in series in the Y direction. Also according to this feeding technology, the plurality of components 15 arranged on the original board 10 are fed to the target board 20, where the pitches in the X direction and the Y direction are enlarged.

In the feeding example of FIG. 14, the three first holding heads 315 pick up the plurality of components 15 three times, and place the plurality of components 15 once. Moreover a second holding head 316 picks up the plurality of components 15 twice, and places the plurality of components 15 once. In other words, the number of feeding in total is five pick-up operations and two placing operations. Note that if the number of feeding is equal to the number of the pick-up operation, the number of feeding is five.

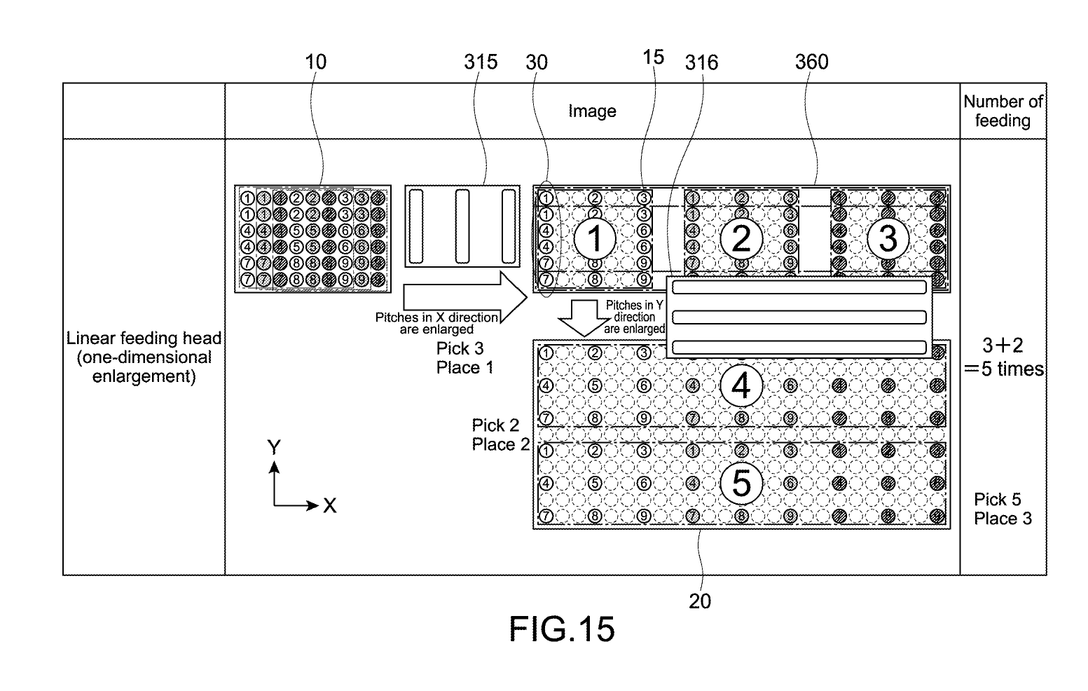

FIG. 15 is a diagram schematically showing a modification example of the component-feeding technology of this embodiment. According to this component-feeding technology, the plurality of first holding heads 315 hold the three first component groups 30, and the three first component groups 30 are arrayed on the medium board 360 in series in the X direction at the first pitches. Moreover the second holding head 316 holds the plurality of components 15 mounted on the medium board 360. For example, according to this feeding technology, the plurality of components 15 arranged on the original board 10 are fed to the target board 20, where the pitches in the X direction and the Y direction are enlarged.

According to the feeding example of FIG. 15, the three first holding heads 315 pick up the plurality of components 15 three times, and place the plurality of components 15 once. Moreover the second holding head 316 picks up the plurality of components 15 twice, and places the plurality of components 15 twice. In other words, the number of feeding in total is five pick-up operations and three placing operations. Note that if the number of feeding is equal to the number of the pick-up operation, the number of feeding is five.

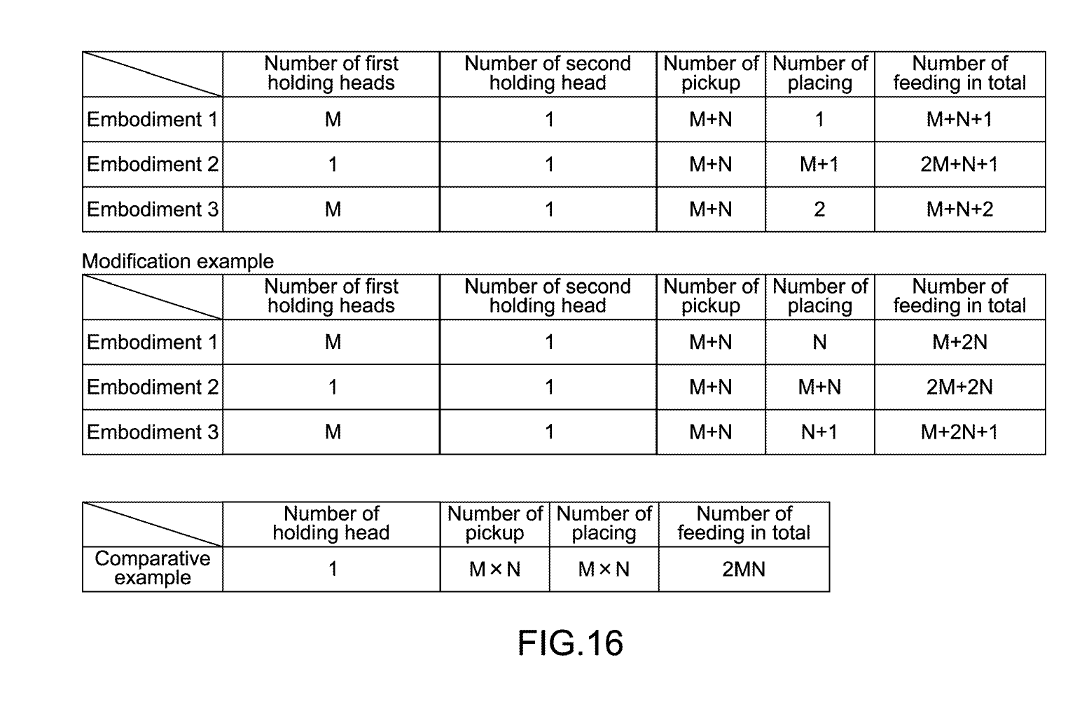

FIG. 16 are tables showing the number of feeding of each of the above-mentioned embodiments and the number of feeding of the above-mentioned comparative example. In the table, N is the necessary number of holding (cull-pitch+1) in the X direction. In the table, M is the necessary number of holding (cull-pitch+1) in the Y direction.

As shown in FIG. 16, according to the component-feeding system of the present technology, component groups to be culled and component groups to be held are arrayed in one direction alternately. As a result, the number of feeding can be reduced. The reason is as follows. If components arrayed in the X axis and components arrayed in the Y axis are culled simultaneously, the number of feeding is decided based on multiplication. To the contrary, if component groups to be culled and component groups to be held are arrayed in one direction alternately, the number of feeding is decided based on addition. If each of M and N is an integer equal to or larger than 2, 1/M+1/N≦1 is satisfied (If M=N=2, the equation has equality) and M+N≦M×N is satisfied. In other words, the number of feeding of the present component-feeding technology can be smaller than the number of feeding of the component-feeding technology of the comparative examples. The larger the cull-pitch, the larger the difference of the number of feeding.

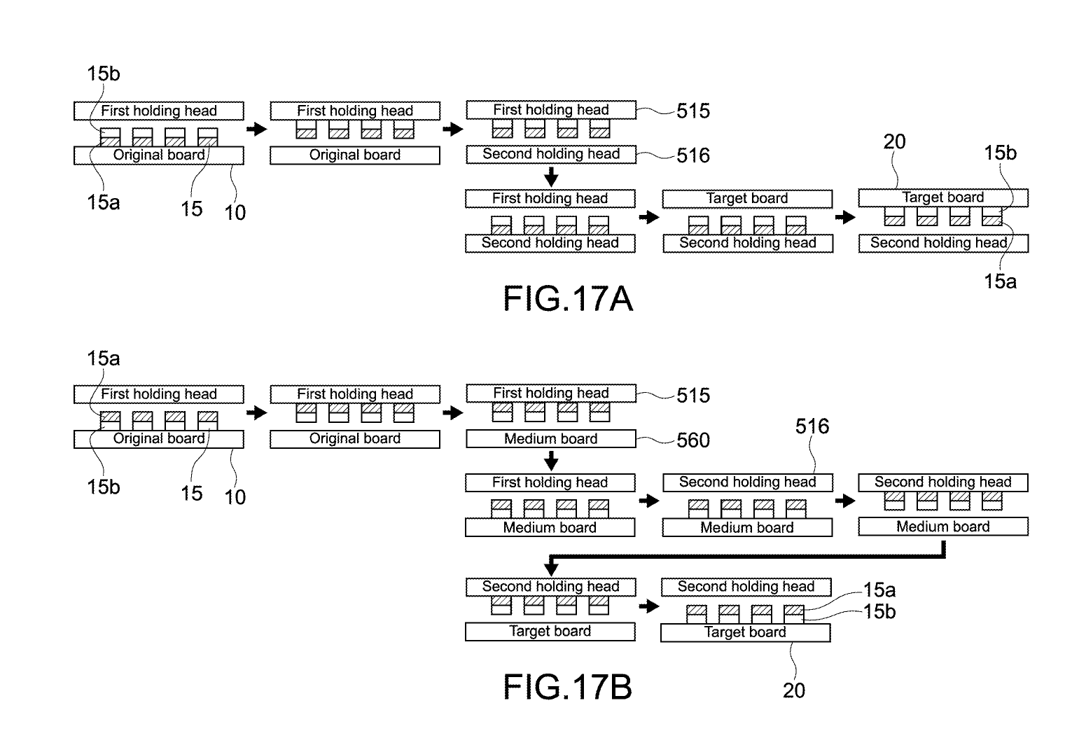

FIGS. 17A-B are diagrams schematically illustrating the front sides and the back sides of the components 15 to be fed. FIG. 17A shows the component-feeding system of the first embodiment. FIG. 17B shows the component-feeding system of the second and third embodiments.

A component to be fed has the front side 15a and the back side 15b. In this case, it is necessary to decide the front side and the back side of a component on the original board 10 in advance in order that the front side and the back side of the component on the target board 20 may be appropriate. As shown in FIG. 17A, when a second holding head 516 holds the plurality of components 15 held by a first holding head 515, the front sides and the back sides of the components 15 on the original board 10 are different from the front sides and the back sides of the components 15 on the target board 20. In view of this, when the plurality of components 15 are arranged on the original board 10, the back sides 15b of the components 15 face the front. If the front sides and the back sides of the components 15 on the target board 20 should be different from the front sides and the back sides of the components 15 on the original board 10 (i.e., if it is necessary to turn over the components 15), the component-feeding technology of the first embodiment of FIG. 17A is advantageous.

Meanwhile, as shown in FIG. 17B, according to the component-feeding technology using a medium board 560, the front sides and the back sides of the components 15 on the original board 10 are the same as the front sides and the back sides of the components 15 on the target board 20. In view of this, when the plurality of components 15 are arranged on the original board 10, the front sides 15a of the components 15 face the front.

In the above-mentioned embodiments, a front-back turning board may be used to change the front sides and the back sides of the components 15 to be fed to the target board 20. The plurality of components 15 are mounted on the front-back turning board, and then the front-back turning board holds the plurality of components 15 again without culling. As a result, the front sides and the back sides of the components to be fed to the target board 20 can be changed. The front-back turning board is provided at an arbitrary position on the feeding path.

For example, mounting the plurality of components 15 on the original board 10 where the front sides face the front is sometimes easier than that where the back sides face the front, and vice versa. It is possible to appropriately feed components depending on conditions of arrangement on the original board 10 by selecting an appropriate embodiment, by using a front-back turning board, and the like.

### Other Embodiments

The present technology is not limited to the above-mentioned embodiments. Other various embodiments may be realized based on the present technology.

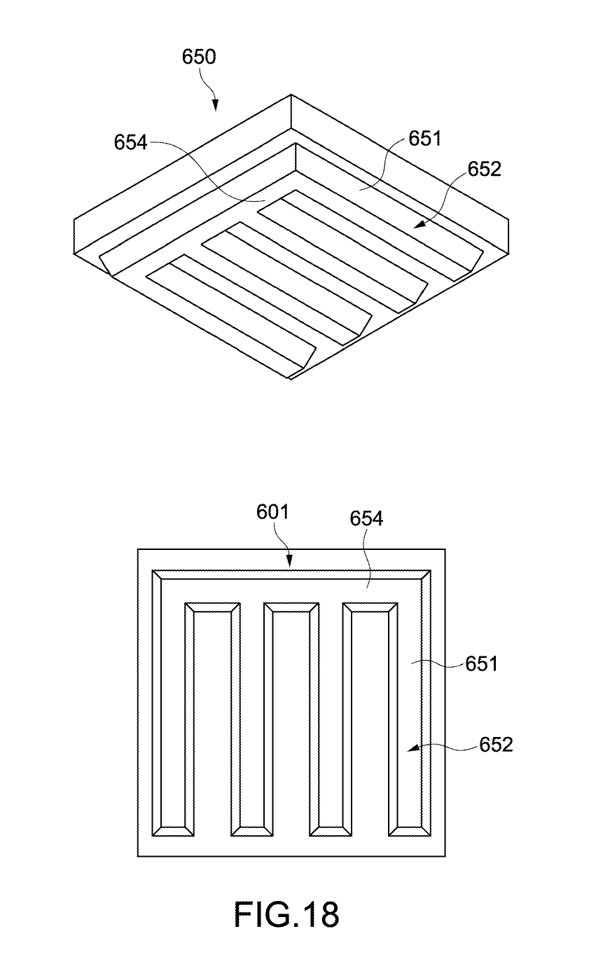

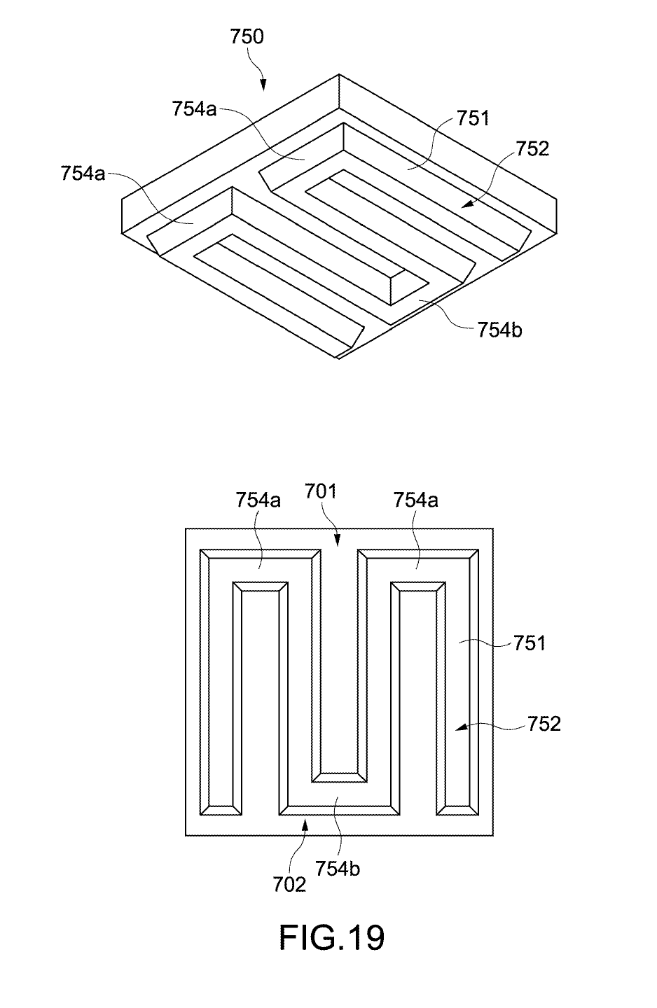

FIGS. 18 to 20 are diagrams schematically showing examples of the structure of a holding head according to other embodiments. For example, as shown in FIGS. 18 and 19, a holder unit may include a plurality of holders and at least one coupler. The coupler couples a plurality of holders. In other words, a plurality of holders may be independent of each other, or may be coupled by a coupler.

In FIG. 18, a holding head 650 includes a plurality of holders 651 and a coupler 654. The coupler 654 couples one ends 601 of the plurality of holders 651 in the extending direction. In FIG. 19, a holding head 750 includes a plurality of holders 751, two couplers 754a, and one coupler 754b. The two couplers 754a are at one ends 701 of the plurality of holders 751 in the extending direction. The coupler 754b is at the other ends 702 of the plurality of holders 751 in the extending direction. One coupler 754a couples the holder 751 at one end with the next holder 751 out of the four holders 751. The other coupler 754a couples the holder 751 at the other end with the next holder 751 out of the four holders 751. The one coupler 754b couples the two holders 751 in the middle. In other words, as shown in the example of FIG. 19, a traversable holder unit 752 is structured. The positions of the couplers are not limited. The couplers may be provided at arbitrary positions as long as the holders can hold components reliably.

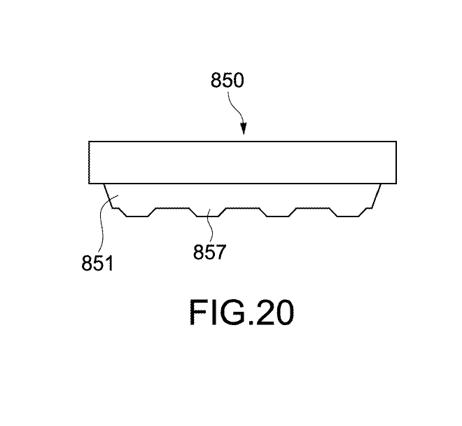

FIG. 20 is a side view showing a holder 851 extending in one direction seen in the direction perpendicular to the extending direction. A holding head 850 includes the holder 851 and a plurality of component holder units 857 formed on the holder 851. The component holder units 857 are convexes, and are formed corresponding to components to be held, respectively. The component holder units 857 are capable of holding a plurality of components reliably. The mechanical strength of the holder 851 can be increased. As described above, the shape of the holder 851 may be designed appropriately as long as it is easy to mold and wash the holder 851.

In the above-mentioned embodiments, one first holding head or three first holding heads, and one second holding head are used. However, the number of the first holding head to be used and the number of the first holding head to be used are not limited.

In the above-mentioned embodiments, the extending direction of the holders of the first holding head is perpendicular to the extending direction of the holders of the second holding head. Alternatively, a first holding head may be rotated, and the rotated first holding head may be used as a second holding head to feed components. For example, the following method may be employed. A first holding head feeds a plurality of components from an original board to a medium board. A plurality of first component groups are mounted on the medium board at the first pitches. After that, the extending direction of a plurality of first holders is changed to the array direction of the plurality of first component groups. In this situation, the first holding head holds the plurality of first component groups. As a result, the necessary number of holding heads can be reduced. The component cost and the like can be reduced.

In the above-mentioned embodiments, the extending direction of the holders of the first holding head is perpendicular to the extending direction of the holders of the second holding head. Alternatively, the extending directions may intersect at an arbitrary angle. Moreover the two array directions of a plurality of components arranged on an original board may not be perpendicular to each other. When a holding head comes in contact with a plurality of components arranged two-dimensionally, the holding head holds a plurality of components arrayed in series in the extending direction of the holders. This direction is the first direction of the present technology.

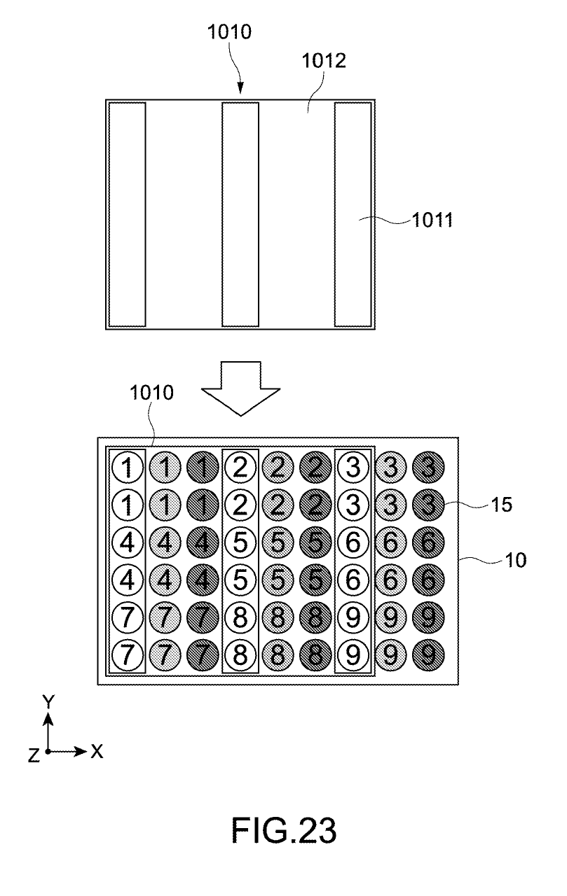

FIG. 23 is a diagram illustrating an example of the structure of a holding head according to another embodiment. A holding head 1010 includes a plurality of holders 1011 and a support 1012. Each of the plurality of holders 1011 and the support 1012 is made of a transparent material transmitting visible light.

As shown in FIG. 23, the plurality of components 15 are arranged on the original board 10. The holding head 1010 is transferred to the position, at which the holding head 1010 faces the original board 10. Then the plurality of components 15 reflect visible light. The reflected visible light passes through the plurality of holders 1011 and the support 1012 in the Z direction (third direction). As a result, a user at the back side (shallower side of the sheet) of the holding head 1010 is capable of visually confirming the plurality of components 15 arranged on the front side (deeper side of the sheet) of the holding head 1010. Moreover it is possible to take an image of the plurality of components 15 from the back side of the holding head 1010.

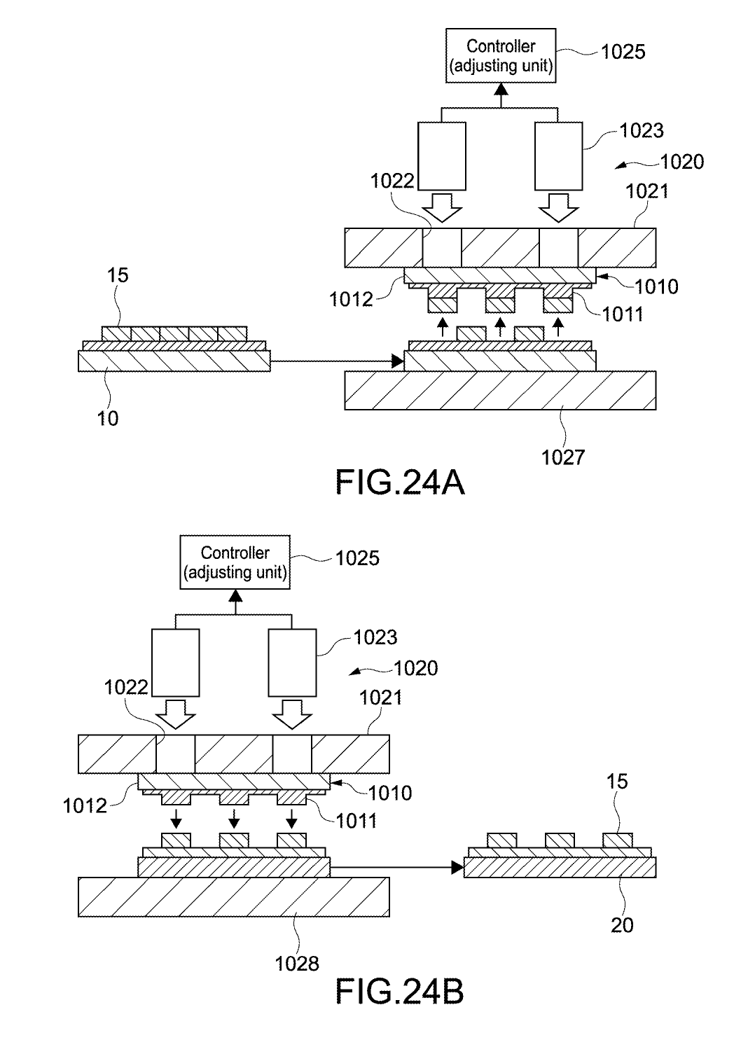

FIGS. 24A-B are diagrams schematically showing an example of the structure of a feeding apparatus 1020 including the holding head 1010 of FIG. 23. The feeding apparatus 1020 includes a holder member 1021. The holder member 1021 holds the back side of the support 1012 of the holding head 1010. Through holes 1022 are formed through the holder member 1021. Visible light passes through the plurality of holders 1011 and the support 1012, passes through the through holes 1022, and travels to the back side of the holder member 1021. Note that in the example of FIG. 23, the through holes 1022 are formed behind the two holders 1011 at the both ends out of the three holders 1011. Alternatively, three through holes 1022 may be formed behind the three holders 1011, respectively.

A camera (image-taking unit) 1023 is arranged behind the through holes 1022. The camera 1023 takes an image with visible light passing through the each of the plurality of holders 1011 and the support 1012. The camera 1023 takes an image of arranged components 15, which face a holder 1011 in front of a through hole 1022. The camera 1023 outputs the taken image to a controller (adjusting unit) 1025. For example, the controller 1025 is configured to control the behaviors of the transferring mechanisms. The controller 1025 is capable of adjusting the relative position of the holding head 1010 and the components 15 (component group) based on the taken image.

For example, the controller 1025 brings the components 15 in proper alignment such that the components 15 are at a predetermined position (typically, center) of an image taken by the camera 1023. A user visually confirms the taken image displayed on a display or the like, and inputs an instruction to adjust the position of the components 15. The controller 1025 adjusts the position of the components 15 in response to the instruction. Alternatively, an image analysis technology or the like may be used, and the controller 1025 may bring the components 15 in proper alignment automatically.

FIG. 24A is a diagram showing an example in which the holding head 1010 holds the components 15. A first board holder 1027 holds the original board 10. Light passes through the plurality of holders 1011 and the support 1012. An image is taken with the transmitted light. Then the components 15 are brought in proper alignment with a high degree of accuracy based on the image (image of the components 15 on the original board 10).

FIG. 24B is a diagram showing an example in which the holding head 1010 mounts the components 15. For example, a second board holder 1028 holds the target board 20. The holding head 1010 holds the components 15, and is arranged above the target board 20. The camera 1023 takes an image. Then the relative position of the holding head 1010 and the original board 10 is adjusted with a high degree of accuracy based on the image.

As described above, according to the present technology, it is possible to bring the components 15 in proper alignment with a high degree of accuracy when the components 15 are both held and mounted. For example, when feeding components between an original board, a first holding head, a medium board, a second holding head, and a target board (as described above in the embodiments), it is possible to adjust the relative positions of the respective members with a high degree of accuracy.

The plurality of holders 1011 may be made of a transparent material (first transparent material), and the kind of the transparent material is not limited. For example, the plurality of holders 1011 may be made of tackifier resin such as silicone resin as described above. Moreover the support 1012 may be made of a transparent material (second transparent material), and the kind of the transparent material is not limited. For example, the support 1012 may be made of quartz glass or the like. If the support 1012 is made of a heat-resistant material having a low coefficient of thermal expansion such as borosilicate glass for example, the dimension error due to thermal expansion or the like can be lower when molding the holding head 1010. Moreover the holding head 1010 may be an adhesive sheet, which is made of a transparent material and has various kinds of properties.

Note that “to be capable of transmitting visible light” not only means to be capable of transmitting light of all the wavelength bands of visible light. “To be capable of transmitting visible light” also means to be capable of transmitting light (for example, light having predetermined color) of some wavelength bands as long as it is possible to bring the components 15 in proper alignment based on a taken image of the components 15 with the light of some wavelength bands. In other words, in the present disclosure, “to be capable of transmitting visible light” means to be capable of transmitting light of at least part of wavelength band of visible light. Moreover a transparent material may be capable of only transmitting light of some wavelength band.

In the feeding apparatus 1020 of FIGS. 24A-B, the through holes 1022 are formed through the holder member 1021 in order to take an image with visible light passing through the holding head 1010. Alternatively, the holder member 1021 may be made of a transparent material transmitting visible light. In this case, the whole holder member 1021 may be made of a transparent material. Alternatively, the portions corresponding to the through holes 1022 of FIGS. 24A-B may be made of a transparent material. Note that the kind of the transparent material is not limited.

Moreover in the structural example of FIG. 23, each of the plurality of holders 1011 and the support 1012 is made of a transparent material transmitting visible light. In this case, each of the plurality of holders 1011 functions as a first transmitting portion capable of transmitting visible light in the Z direction. Moreover the support 1012 functions as a second transmitting portion capable of transmitting visible light in the Z direction, the visible light passing through the first transmitting portion.

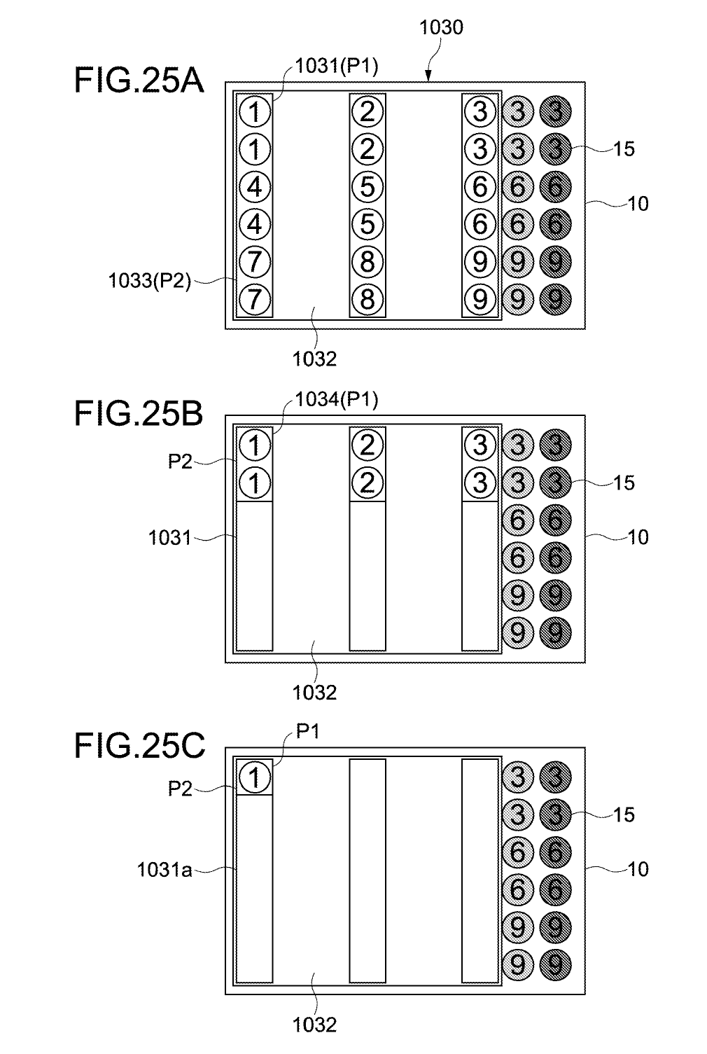

Meanwhile, as shown in FIGS. 25A-C, the structure of the first transmitting portion configured to transmit visible light can be designed arbitrarily. The structure of the second transmitting portion configured to transmit visible light can be designed arbitrarily. For example, as shown in FIG. 25A, a holding head 1030 includes a plurality of holders 1031. Each holder 1031 is made of a transparent material. Each holder 1031 functions as a first transmitting portion P1. Meanwhile, a support 1032 includes portions 1033. The portions 1033 couple the support 1032 and the plurality of holders 1031. Only the portions 1033 out of the support 1032 are made of a transparent material. In other words, in this example, the transparent portions 1033 of the support 1032 function as second transmitting portions P2.

Moreover in the example of FIG. 25B, part of each of the plurality of holders 1031 is made of a transparent material. In other words, only a portion 1034 at one end of each holder 1031 is transparent. The transparent portions 1034 function as the first transmitting portions P1. Moreover some portions of the support 1032 are made of a transparent material. Those portions couple the support 1032 and the transparent portions 1034 of the holders 1031. Those portions function as the second transmitting portions P2.

Moreover in the example of FIG. 25C, one holder 1031a out of the plurality of holders 1031 includes the first transmitting portion P1. The first transmitting portion P1 is at one end of the holder 1031a. The support 1032 includes the second transmitting portion P2 at the position corresponding to the first transmitting portion P1.

As described above, at least one of the plurality of holders 1031 includes the first transmitting portion P1. The second transmitting portion P2 is at a position capable of transmitting visible light passing through the first transmitting portion P1. An image is taken with visible light passing through the first and second transmitting portions P1 and P2. It is therefore possible to bring the components 15 in proper alignment with a high degree of accuracy.

The first and second holding heads are used in the above-mentioned embodiments. In this case, each holding head includes a transmitting portion transmitting visible light. Here, the transmitting portion (specifically, transmitting portion of first holder) of the first holding head will be sometimes referred to as a first transmitting portion. Moreover the transmitting portion (specifically, transmitting portion of second holder) of the second holding head will be sometimes referred to as a second transmitting portion.

Moreover a plurality of cameras are sometimes provided in order to take an image with visible light passing through the transmitting portion of the first holding head, and in order to take an image with visible light passing through the transmitting portion of the second holding head. In this case, an image-taking unit is configured to include the plurality of cameras. Moreover an optical system or the like may be used arbitrarily, and the optical system guides visible light to each camera. A controller (adjusting unit) is capable of adjust the relative position of the first holding head and the first component groups with a high degree of accuracy based on an image taken by the image-taking unit. Moreover the controller (adjusting unit) is capable of adjust the relative position of the second holding head and the second component groups with a high degree of accuracy based on an image taken by the image-taking unit.

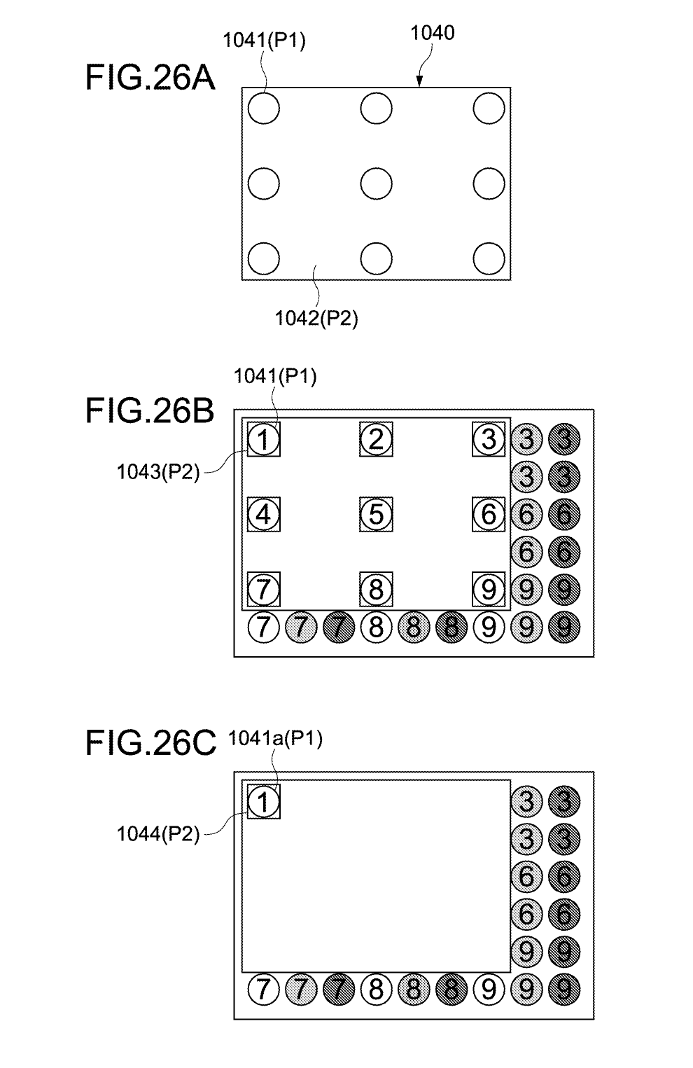

First transmitting portions are formed on a plurality of holders of a holding head, and second transmitting portions are formed on a support supporting the holders. This technology is applicable to holders having any shape. In other words, this technology is applicable not only to the holding head including the linear holders 1011 of FIGS. 25A-C and the like, but also to a holding head 1040 including island holding convexes (holders) 1041 of FIGS. 26A-C and the like.

For example, as shown in FIG. 26A, all the holding convexes 1041 may be made of a transparent material, and the first transmitting portion P1 may thus be structured. Moreover the entire support 1042 may be made of a transparent material, and the second transmitting portion P2 may thus be structured. Moreover as shown in FIG. 26B, all the holding convexes 1041 may be structured as the first transmitting portions P1. Portions 1043 couple the support 1042 and the holding convexes 1041. The portions 1043 may be structured as the second transmitting portions P2. Moreover as shown in FIG. 26C, only one holding convex 1041a may be the first transmitting portion P1. A portion 1044 couples the support 1042 and the holding convex 1041a. The portion 1044 may be the second transmitting portion P2. The holding head 1040 having each structure is capable of bringing the components in proper alignment with a high degree of accuracy.

Alternatively, the present technology is applicable to holders, each of which has a structure different from the island holding convexes 1041. In other words, holders come in contact with components in a predetermined direction, and are capable of holding the components by using adhesive power. The holders include a first transmitting portion. The first transmitting portion is capable of transmitting visible light in the predetermined direction. Moreover a support supports the holders. The support includes a second transmitting portion. The second transmitting portion is capable of transmitting visible light passing through the first transmitting portion. The shape of each holder is not limited as long as a holding head has the above-mentioned structure. Moreover any feeding method other than the feeding method including enlarging the pitches between components may be used as long as a holding head has the above-mentioned structure. Also in those cases, the above-mentioned effects can be obtained. For example, it is possible to observe components and holders simultaneously by using an image taken with visible light passing through the first and second transmitting portions. So it is possible to bring the components in proper alignment with a high degree of accuracy.

Moreover an image of components can be taken directly from the back side of a holding head. So it is not necessary to form an alignment mark on an original board or the like. Cost can therefore be reduced. Meanwhile, an alignment mark may be formed on an original board or the like, and an image of the alignment mark may be directly taken from the back side of the holding head. Also in this case, it is possible to adjust the position with a high degree of accuracy.

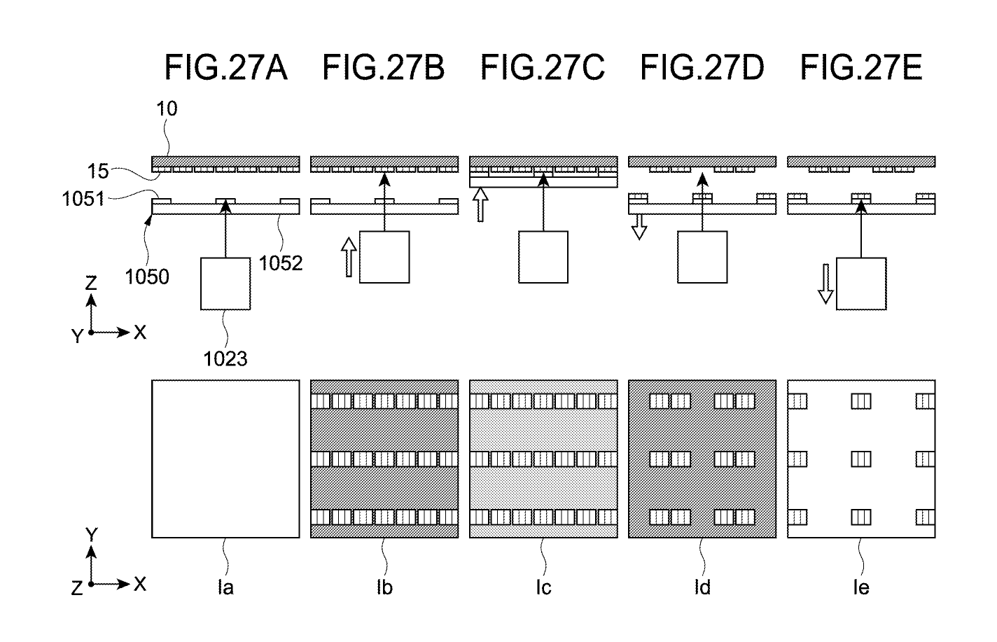

FIGS. 27A-E are diagrams each illustrating the focus of a camera, which takes images of components to be held. The upper diagram of each of FIGS. 27A-E shows the position of the camera 1023, which takes an image of components to be held. In the upper diagram of each of FIGS. 27A-E, the focus position of the camera is pointed by an arrow extending from the camera 1023. The lower diagram of each of FIGS. 27A-E schematically shows an in-focus image taken by the camera.

Each of FIGS. 27A and 27B shows that components are yet to be held. A holding head 1050 faces the original board 10. Note that the holding head 1050 includes three linear holders 1051 extending in the Y direction, and a support 1052 holding the holders 1051. Each of the three holders 1051 and the support 1052 is made of a transparent material. The three holders 1051 and the support 1052 function as first and second transmitting portions, respectively. Moreover in each of FIGS. 27A-E, the holder member at the feeding apparatus side is not shown.

In FIG. 27A, an image Ia of the holding head 1050 is taken, where the holding head 1050 is yet to hold components (before holding). In FIG. 27B, an image Ib of the original board 10 is taken (before holding). In FIG. 27C, an image Ic is taken, where the plurality of holders 1051 are in contact with the components 15 on the original board 10. In FIG. 27D, an image Id of the original board 10 is taken (after holding). In FIG. 27E, an image Ie of the holding head 1050 is taken, where the holding head 1050 holds the components 15 (after holding).

Typically, an image of the holding head 1050 and the original board 10, which are close to each other to some extent, is used to adjust the relative position of the holding head 1050 and the plurality of components 15. In this image, both the components 15 and the holders 1051 are in focus (image similar to the image Ic). It is possible to bring the components 15 in proper alignment with a high degree of accuracy. Alternatively, the components 15 may be brought in proper alignment by using each of the images Ia and Ib of FIGS. 27A and 27B (before holding).

In addition to this alignment, the status of the holding head 1050 and the components 15 may be examined, confirmed, and the like, based on images taken by the camera 1023. For example, the status of the holding head 1050 (before holding) can be examined, the components 15 on the original board 10 (before holding) can be examined, and the like, based on the images Ia to Ie of FIGS. 27A to 27E. Moreover the contact status between the holders 1051 and the components 15 can be examined, the hold status of the holding head 1050 holding the components 15 can be examined, and the like. Moreover the status of the components 15 on the original board 10 (after holding) can be examined.

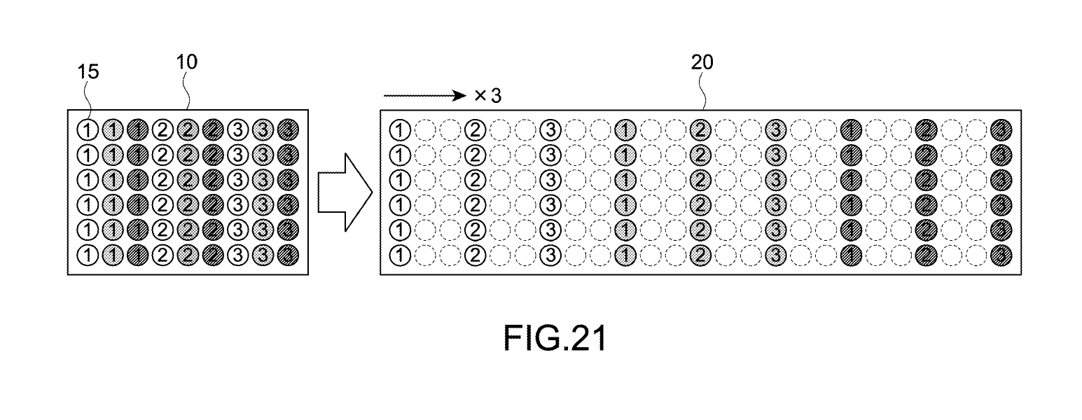

FIG. 21 is a diagram illustrating another example of the present component-feeding technology. As shown in FIG. 21, the holding head of the present technology may enlarge the pitches only in the X direction or the Y direction of the plurality of components 15 arranged on the original board 10, and feed the plurality of components 15. This component-feeding technology is within the scope of the present component-feeding technology.

According to the feeding method of the present technology, a plurality of components arrayed in series in one direction may be held simultaneously without culling components in this direction. In other words, according to this feeding method, a plurality of object groups arrayed in a second direction are held. The object group includes a plurality of objects arrayed in series in a first direction out of a plurality of objects. The first direction is different from the second direction. The structure of a holding head used in this feeding method may not be limited. Moreover two or more object groups adjacent to each other in the second direction may be held simultaneously. In other words, this feeding method is not limited to the method including holding an object group one by one.

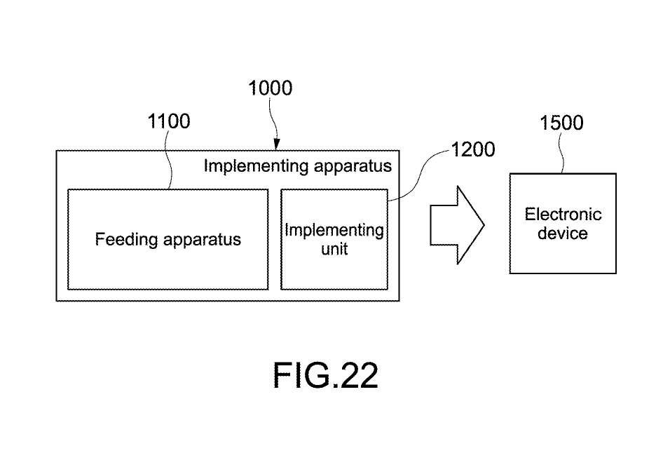

FIG. 22 is a diagram schematically showing an example of the structure of an implementing apparatus of the present technology. An implementing apparatus 1000 includes an above-mentioned feeding apparatus 1100 of the present technology, and an implementing unit 1200. The first and second holding heads hold a plurality of components. The plurality of components are fed to a target board at last. The implementing unit 1200 implements the plurality of components on the target board. The structure of the implementing unit 1200 is not limited. The implementing unit 1200 may have an arbitrary mechanism configured to receive a target board ejected from the feeding apparatus 1100 and to implement components on the target board. Alternatively, the implementing unit 1200 may have a mechanism configured to implement components on a target board inside the feeding apparatus 1100. The time the feeding apparatus 1100 takes to feed components can therefore be reduced. The total processing time to implement components can therefore be reduced.

Various kinds of electronic devices 1500 can be manufactured. Each electronic device 1500 includes a board manufactured as shown in FIG. 22, on which components are implemented by the implementing apparatus 1000. For example, the manufactured electronic device 1500 may be an arbitrary apparatus such as a display apparatus, an electrical household appliance, or a mobile information terminal (PDA: Personal Digital Assistant).

As described above, the following effects may be obtained according to the present technology.

It is easy to manufacture a molding die.

A molding die requires easy maintenance.

It is easy to release a molding die.

It is easy to wash a molding die and to use the molding die again and again.

It is easy to apply resin to a molding die.

The release resistance is reduced when manufacturing a feeding head (holding head).

A feeding head requires easy maintenance.

It is easy to wash a feeding head and to use the feeding head again and again.

The physical strength of a feeding head is increased.

The number of feeding is small.

Components can be turned over.

Components are brought in proper alignment with a high degree of accuracy.

The effects described in the present disclosure including those effects are merely examples and are not limited. Moreover although the plurality of effects are described above, it does not necessarily mean that those effects are obtained simultaneously. It means that at least one of the above-mentioned effects can be obtained depending on a condition or the like. As a matter of course, effects not described in the present disclosure may be obtained.

At least two of the characterizing parts of the above-mentioned embodiments can be combined. In other words, the various characterizing parts of the above-mentioned embodiments can be combined arbitrarily without depending on the respective embodiments.

Note that the present technology may employ the following structures.
(1) A holding head, including:

a holder unit including a plurality of holders, the plurality of holders extending in a first direction, the plurality of holders being arrayed in a second direction at a predetermined pitch, the first direction being different from the second direction, each of the plurality of holders being capable of holding an object group, the object group including a plurality of objects arrayed in series in the first direction out of a plurality of objects arranged two-dimensionally; and

a support supporting the holder unit.
(2) The holding head according to (1), in which

the plurality of holders protrude in a third direction, the third direction being perpendicular to the first direction and the second direction.
(3) The holding head according to (2), in which

at least one of the plurality of holders includes a first transmitting portion, the first transmitting portion being capable of transmitting visible light in the third direction, and

the support includes a second transmitting portion, the second transmitting portion being capable of transmitting the visible light in the third direction, the visible light passing through the first transmitting portion.
(4) The holding head according to (3), in which

the first transmitting portion is made of a transparent material, the transparent material being configured to transmit the visible light, and

the second transmitting portion is made of a transparent material, the transparent material being configured to transmit the visible light.
(5) The holding head according to (4), in which

each of the plurality of holders is made of a first transparent material, and

the support is made of a second transparent material.
(6) The holding head according to any one of (1) to (5), in which

the first direction is perpendicular to the second direction.
(7) The holding head according to any one of (1) to (6), in which

each of the plurality of holders holds the object group by using adhesive power.
(8) The holding head according to any one of (1) to (7), in which

the cross-sectional shape of each of the plurality of holders seen in the first direction is substantially trapezoidal, the long side of the trapezoid being the support side, the short side being the side in contact with the objects.
(9) The holding head according to any one of (1) to (8), in which

the holder unit includes a coupler, the coupler coupling the plurality of holders.
(10) A feeding apparatus, including:

at least one first holding head, the first holding head including a plurality of first holders, the plurality of first holders extending in a first direction, the plurality of first holders being arrayed in a second direction at a first pitch, the first direction being different from the second direction, each of the plurality of first holders being capable of holding a first object group, the first object group including a plurality of objects arrayed in series in the first direction out of a plurality of objects arranged two-dimensionally; and

a driver configured
to transfer the at least one first holding head, and
to cause the at least one first holding head to hold the first object groups.
(11) The feeding apparatus according to (10), further including:

a second holding head including a plurality of second holders, the plurality of second holders extending in the second direction, the plurality of second holders being arrayed in the first direction at a second pitch, each of the plurality of second holders being capable of holding a second object group, the second object group including a plurality of objects arrayed in series in the second direction out of the plurality of objects arranged two-dimensionally, in which

the driver is configured to cause the second holding head to hold a plurality of second object groups, the second object group including a plurality of objects arrayed in series in the second direction at the first pitch out of the plurality of objects held by the first holding head.
(12) The feeding apparatus according to (11), in which

the at least one first holding head includes a plurality of first holding heads, and

the driver is configured
to fix the plurality of first holding heads such that the plurality of first object groups held by the plurality of first holding heads are arrayed in series in the first direction or arrayed in series in the second direction at the first pitch, and
to cause the second holding head to hold the plurality of objects held by the plurality of first holding heads.
(13) The feeding apparatus according to (10), further including:

a second holding head including a plurality of second holders, the plurality of second holders extending in the second direction, the plurality of second holders being arrayed in the first direction at a second pitch, each of the plurality of second holders being capable of holding a second object group, the second object group including a plurality of objects arrayed in series in the second direction out of the plurality of objects arranged two-dimensionally; and

a mount, the plurality of first object groups held by the first holding head being mounted on the mount, in which

the driver is configured to cause the second holding head to hold a plurality of second object groups, the second object group including a plurality of objects arrayed in series in the second direction at the first pitch out of the plurality of objects mounted on the mount.
(14) The feeding apparatus according to (13), in which

the driver is configured to cause the first holding head to hold the plurality of first object groups a plurality of times such that the plurality of first object groups held by the first holding head are arrayed on the mount in series in the first direction or arrayed on the mount in series in the second direction at the first pitch.
(15) The feeding apparatus according to (13), in which

the at least one first holding head includes a plurality of first holding heads, and

the driver is configured to cause the plurality of first holding heads to hold the plurality of first object groups such that the plurality of first object groups held by the plurality of first holding heads are arrayed on the mount in series in the first direction or arrayed on the mount in series in the second direction at the first pitch.
(16) The feeding apparatus according to (10), further including:

a mount, the plurality of first object groups held by the first holding head being mounted on the mount, in which

the driver is configured
to cause the plurality of first holders to extend in a direction, in which the plurality of first object groups mounted on the mount being arrayed at the first pitch, and
to cause the first holding head to hold the plurality of first object groups in this situation.
(17) The feeding apparatus according to any one of (10) to (16), in which

at least one of the plurality of first holders includes a first transmitting portion, the first transmitting portion being capable of transmitting visible light in a third direction, the third direction being perpendicular to the first direction and the second direction, and

the feeding apparatus further includes
an image-taking unit configured to take an image with the visible light passing through the first transmitting portion, and
an adjusting unit configured to adjust the relative position of the at least one first holding head and the first object groups based on the image taken by the image-taking unit.
(18) The feeding apparatus according to (17), in which

at least one of the plurality of second holders includes a second transmitting portion, the second transmitting portion being capable of transmitting visible light in the third direction,

the image-taking unit is configured to take an image with the visible light passing through the second transmitting portion, and

the adjusting unit is configured to adjust the relative position of the second holding head and the second object groups based on the image taken by the image-taking unit.

It should be understood by those skilled in the art that various modifications, combinations, sub-combinations and alterations may occur depending on design requirements and other factors insofar as they are within the scope of the appended claims or the equivalents thereof.

What is claimed is:

1. A holding head, comprising:
a holder unit including a plurality of holders, the plurality of holders extending in a first direction, the plurality of holders being arrayed in a second direction at a predetermined pitch, the first direction being different from the second direction, each of the plurality of holders being capable of holding an object group, the object group including a plurality of objects arrayed in series in the first direction out of a plurality of objects arranged two-dimensionally; and
a support supporting the holder unit.

2. The holding head according to claim 1, wherein
the plurality of holders protrude in a third direction, the third direction being perpendicular to the first direction and the second direction.

3. The holding head according to claim 2, wherein
at least one of the plurality of holders includes a first transmitting portion, the first transmitting portion being capable of transmitting visible light in the third direction, and
the support includes a second transmitting portion, the second transmitting portion being capable of transmitting the visible light in the third direction, the visible light passing through the first transmitting portion.

4. The holding head according to claim 3, wherein
the first transmitting portion is made of a transparent material, the transparent material being configured to transmit the visible light, and
the second transmitting portion is made of a transparent material, the transparent material being configured to transmit the visible light.

5. The holding head according to claim 4, wherein
each of the plurality of holders is made of a first transparent material, and
the support is made of a second transparent material.

6. The holding head according to claim 1, wherein
the first direction is perpendicular to the second direction.

7. The holding head according to claim 1, wherein
each of the plurality of holders holds the object group by using adhesive power.

8. The holding head according to claim 1, wherein
the cross-sectional shape of each of the plurality of holders seen in the first direction is substantially trapezoidal, the long side of the trapezoid being the support side, the short side being the side in contact with the objects.

9. The holding head according to claim 1, wherein
the holder unit includes a coupler, the coupler coupling the plurality of holders.

10. A feeding apparatus, comprising:
at least one first holding head, the first holding head including a plurality of first holders, the plurality of first holders extending in a first direction, the plurality of first holders being arrayed in a second direction at a first pitch, the first direction being different from the second direction, each of the plurality of first holders being capable of holding a first object group, the first object group including a plurality of objects arrayed in series in the first direction out of a plurality of objects arranged two-dimensionally; and
a driver configured
to transfer the at least one first holding head, and
to cause the at least one first holding head to hold the first object groups.

11. The feeding apparatus according to claim 10, further comprising:
a second holding head including a plurality of second holders, the plurality of second holders extending in the second direction, the plurality of second holders being arrayed in the first direction at a second pitch, each of the plurality of second holders being capable of holding a second object group, the second object group including a plurality of objects arrayed in series in the second direction out of the plurality of objects arranged two-dimensionally, wherein
the driver is configured to cause the second holding head to hold a plurality of second object groups, the second object group including a plurality of objects arrayed in series in the second direction at the first pitch out of the plurality of objects held by the first holding head.

12. The feeding apparatus according to claim 11, wherein
the at least one first holding head includes a plurality of first holding heads, and
the driver is configured
to fix the plurality of first holding heads such that the plurality of first object groups held by the plurality of first holding heads are arrayed in series in the first direction or arrayed in series in the second direction at the first pitch, and
to cause the second holding head to hold the plurality of objects held by the plurality of first holding heads.

13. The feeding apparatus according to claim 10, further comprising:
a second holding head including a plurality of second holders, the plurality of second holders extending in the second direction, the plurality of second holders being arrayed in the first direction at a second pitch, each of the plurality of second holders being capable of holding a second object group, the second object group including a plurality of objects arrayed in series in the second direction out of the plurality of objects arranged two-dimensionally; and
a mount, the plurality of first object groups held by the first holding head being mounted on the mount, wherein
the driver is configured to cause the second holding head to hold a plurality of second object groups, the second object group including a plurality of objects arrayed in series in the second direction at the first pitch out of the plurality of objects mounted on the mount.

14. The feeding apparatus according to claim 13, wherein
the driver is configured to cause the first holding head to hold the plurality of first object groups a plurality of times such that the plurality of first object groups held by the first holding head are arrayed on the mount in series in the first direction or arrayed on the mount in series in the second direction at the first pitch.

15. The feeding apparatus according to claim 13, wherein
the at least one first holding head includes a plurality of first holding heads, and
the driver is configured to cause the plurality of first holding heads to hold the plurality of first object groups such that the plurality of first object groups held by the plurality of first holding heads are arrayed on the mount in series in the first direction or arrayed on the mount in series in the second direction at the first pitch.

16. The feeding apparatus according to claim 10, further comprising:
a mount, the plurality of first object groups held by the first holding head being mounted on the mount, wherein
the driver is configured
to cause the plurality of first holders to extend in a direction, in which the plurality of first object groups mounted on the mount being arrayed at the first pitch, and
to cause the first holding head to hold the plurality of first object groups in this situation.

17. The feeding apparatus according to claim 10, wherein
at least one of the plurality of first holders includes a first transmitting portion, the first transmitting portion being capable of transmitting visible light in a third direction, the third direction being perpendicular to the first direction and the second direction, and
the feeding apparatus further comprises
an image-taking unit configured to take an image with the visible light passing through the first transmitting portion, and
an adjusting unit configured to adjust the relative position of the at least one first holding head and the first object groups based on the image taken by the image-taking unit.

18. The feeding apparatus according to claim 17, wherein
at least one of the plurality of second holders includes a second transmitting portion, the second transmitting portion being capable of transmitting visible light in the third direction,
the image-taking unit is configured to take an image with the visible light passing through the second transmitting portion, and
the adjusting unit is configured to adjust the relative position of the second holding head and the second object groups based on the image taken by the image-taking unit.

19. A feeding method, comprising:
preparing a plurality of objects arranged two-dimensionally in an original place;
holding a plurality of first object groups with a plurality of first holders of a first holding head, the plurality of first holders extending in a first direction, the plurality of first holders being arrayed in a second direction at a first pitch, the first direction being different from the second direction, each of the plurality of first object groups including a plurality of objects arrayed in series in the first direction out of the plurality of objects; and
feeding the plurality of held first object groups to a target place.

20. The feeding method according to claim 19, further comprising:
holding a plurality of second object groups with a plurality of second holders of a second holding head, the plurality of second holders extending in the second direction, the plurality of second holders being arrayed in the first direction at a second pitch, each of the plurality of second object groups including a plurality of objects arrayed in series in the second direction at the first pitch out of the plurality of objects held by the first holding head; and
feeding the plurality of held second object groups to the target place.

21. An implementing apparatus, comprising:
a first holding head including a plurality of first holders, the plurality of first holders extending in a first direction, the plurality of first holders being arrayed in a second direction at a first pitch, the first direction being different from the second direction, each of the plurality of first holders being capable of holding a first component group, the first component group including a plurality of components arrayed in series in the first direction out of a plurality of components arranged two-dimensionally; and
an implementing unit configured to implement a plurality of first component groups held by the first holding head on a board.

22. The implementing apparatus according to claim 21, further comprising:
a second holding head including a plurality of second holders, the plurality of second holders extending in the second direction, the plurality of second holders being arrayed in the first direction at a second pitch, each of the plurality of second holders being capable of holding a second component group, the second component group including a plurality of components arrayed in series in the second direction out of the plurality of components arranged two-dimensionally; and
a driver configured to cause the second holding head to hold a plurality of second component groups, the second component group including a plurality of components arrayed in series in the second direction at the first pitch out of the plurality of components held by the first holding head, wherein
the implementing unit is configured to implement the plurality of second component groups held by the second holding head on the board.

23. An implementing method, comprising:
preparing a plurality of components arranged two-dimensionally in an original place;
holding a plurality of component groups with a plurality of holders of a holding head, the plurality of holders extending in a first direction, the plurality of holders being arrayed in a second direction at a predetermined pitch, the first direction being different from the second direction, each of the plurality of component groups including a plurality of components arrayed in series in the first direction out of the plurality of components; and
implementing the plurality of held component groups on a board.

24. A electronic device, comprising:
a board manufactured by
preparing a plurality of components arranged two-dimensionally in an original place,
holding a plurality of component groups with a plurality of holders of a holding head, the plurality of holders extending in a first direction, the plurality of holders being arrayed in a second direction at a predetermined pitch, the first direction being different from the second direction, the component group including a plurality of components arrayed in series in the first direction out of the plurality of components, and
by implementing the plurality of held component groups on the board.

25. A feeding method, comprising:
preparing a plurality of objects arranged two-dimensionally in an original place;
holding a plurality of object groups, the object group including a plurality of objects arrayed in series in a first direction out of the plurality of objects, the plurality of object groups being arrayed in a second direction, the first direction being different from the second direction; and
feeding the plurality of held object groups to a target place.

26. A holding head, comprising:
a holder including a first transmitting portion, the first transmitting portion being capable of transmitting visible light in a predetermined direction, the holder coming in contact with an object in the predetermined direction, the holder being capable of holding the object by using adhesive power; and
a support supporting the holder, the support including a second transmitting portion, the second transmitting portion being capable of transmitting the visible light in the predetermined direction, the visible light passing through the first transmitting portion.
